(19) United States
(12) Patent Application Publication
(10) Pub. No.: US 2024/0079447 A1
(43) Pub. Date: Mar. 7, 2024

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu (TW); Chun-Sheng LIANG, Hsinchu (TW); Kuo-Hua PAN, Hsinchu (TW); Chih-Hao CHANG, Hsinchu (TW); Jhon-Jhy LIAW, Hsinchu (TW)

(73) Assignee: Taiwan Semiconductor Manufacturing Company, Ltd., Hsinchu (TW)

(21) Appl. No.: 18/164,204

(22) Filed: Feb. 3, 2023

Related U.S. Application Data
(60) Provisional application No. 63/403,936, filed on Sep. 6, 2022.

(51) Int. Cl. H01L 29/06; H01L 21/8234; H01L 29/08; H01L 29/423; H01L 29/66; H01L 29/786

(52) U.S. Cl. CPC H01L 29/0673; H01L 21/823412; H01L 21/823418; H01L 21/823481; H01L 29/0847; H01L 29/42392; H01L 29/66545; H01L 29/78696

(57) ABSTRACT

Semiconductor structures and methods for manufacturing the same are provided. The semiconductor structure includes a first stack structure formed over a substrate, and the first stack structure includes a plurality of nanostructures that extend along a first direction. The semiconductor structure includes a second stack structure formed adjacent to the first stack structure, and the second stack structure includes a plurality of nanostructures that extend along the first direction. The semiconductor structure includes a first gate structure formed over the first stack structure, and the first gate structure extends along a second direction. The semiconductor structure also includes a dielectric wall between the first stack structure and the second stack structure, and the dielectric wall includes a low-k dielectric material, and the dielectric wall is connected to the first stack structure and the second stack structure.

### CROSS REFERENCE TO RELATED APPLICATIONS

This application claims the benefit of U.S. Provisional Application No. 63/403,936, filed on Sep. 6, 2022, and the entirety of which is incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1F show perspective views of intermediate stages of manufacturing a semiconductor structure, in accordance with some embodiments.

FIGS. 1D′ to 1F′ show perspective views of intermediate stages of manufacturing a semiconductor structure, in accordance with some embodiments.

FIGS. 2A to 2J show cross-sectional representations of various stages of manufacturing the semiconductor structure shown along line A-A′ in FIG. 1F, in accordance with some embodiments.

FIG. 2J′ shows a cross-sectional view of a semiconductor structure, in accordance with some embodiments.

FIG. 2J″ shows a cross-sectional view of a semiconductor structure, in accordance with some embodiments.

FIG. 3 shows a perspective view of the semiconductor structure after FIG. 2J, in accordance with some embodiments.

FIG. 3′ shows a perspective view of the semiconductor structure 100c, after FIG. 2J′, in accordance with some embodiments.

FIGS. 4A to 4G show cross-sectional representations of various stages of manufacturing the semiconductor structure shown along line B-B′ in FIG. 1F, in accordance with some embodiments.

FIGS. 5A-5B shows a cross-sectional view of a semiconductor structure, in accordance with some embodiments.

FIGS. 6A to 6D show perspective views of intermediate stages of manufacturing a semiconductor structure, in accordance with some embodiments.

FIGS. 7A to 7F show cross-sectional representations of various stages of manufacturing the semiconductor structure shown along line A-A′ in FIG. 6D, in accordance with some embodiments.

FIG. 7F′ shows a cross-sectional view of a semiconductor structure, in accordance with some embodiments.

FIGS. 8A to 8M show cross-sectional representations of various stages of manufacturing the semiconductor structure shown along an S/D region, in accordance with some embodiments.

FIGS. 8D′ to 8E′ show cross-sectional representations of intermediate stages of manufacturing a semiconductor structure, in accordance with some embodiments.

FIG. 8M′ shows a cross-sectional view of a semiconductor structure, in accordance with some embodiments.

FIGS. 9A-9B show a cross-sectional views of the semiconductor structure, in accordance with some embodiments.

FIG. 10 shows a cross-sectional view of a semiconductor structure, in accordance with some embodiments.

FIG. 10′ shows a cross-sectional view of a semiconductor structure, in accordance with some embodiments.

FIG. 11 shows a cross-sectional view of the semiconductor structure, in accordance with some embodiments.

FIG. 12 shows a cross-sectional view of a semiconductor structure, in accordance with some embodiments.

FIG. 12′ shows a cross-sectional view of a semiconductor structure, in accordance with some embodiments.

FIG. 13 shows a cross-sectional view of the semiconductor structure 100m, in accordance with some embodiments.

FIGS. 14A to 14H show cross-sectional representations of various stages of manufacturing the semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include nanostructures formed over a substrate. A gate structure wraps around the nanostructures and a source/drain (S/D) structure formed adjacent to the gate structure. An S/D contact structure is formed over the S/D structure. A dielectric wall is formed below the gate structure and the S/D contact structure. The dielectric wall is connected to the nanostructures. The dielectric wall includes a low-k material to reduce the capacitance of the semiconductor structure. In addition, the dielectric wall is formed by a flowable material, and the dielectric wall may be void free or seam free. Therefore, the performance of the semiconductor structure is improved. Source/drain(S/D) region(s) S/D structures may refer to a source or a drain, individually or collectively dependent upon the context.

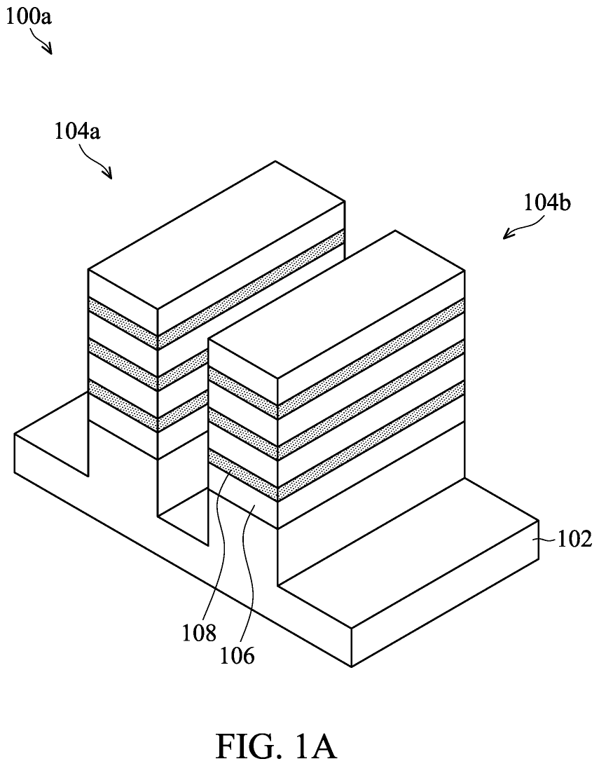

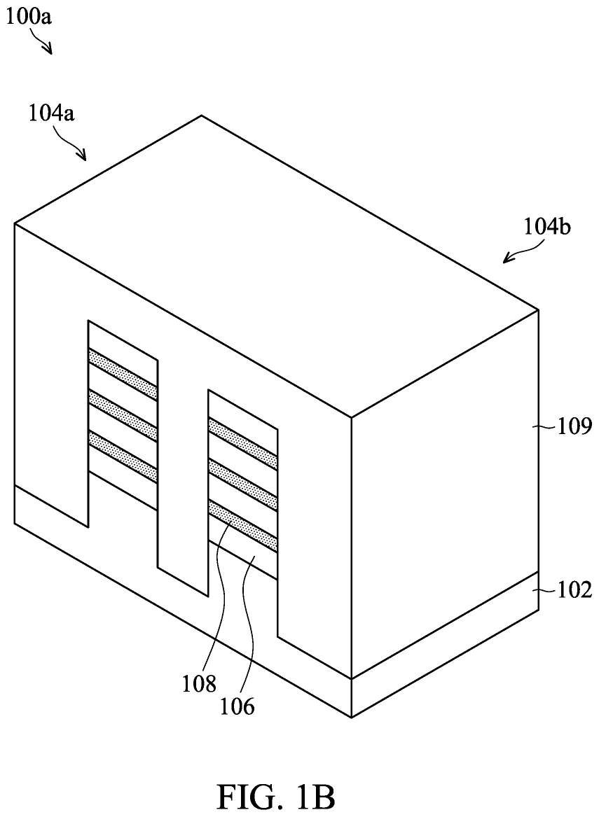

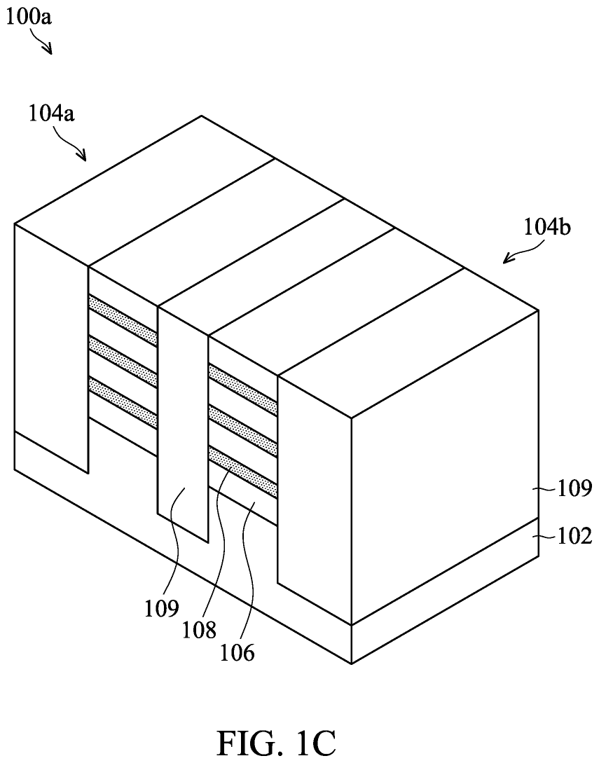

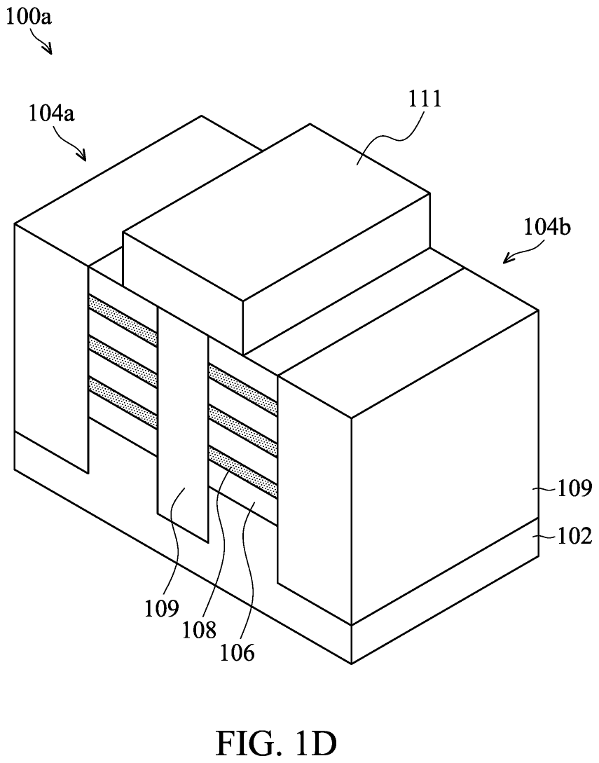

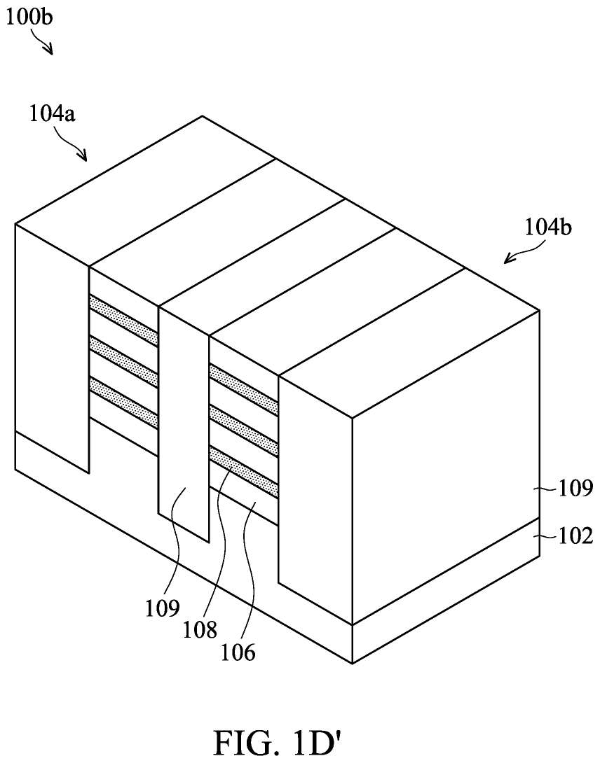

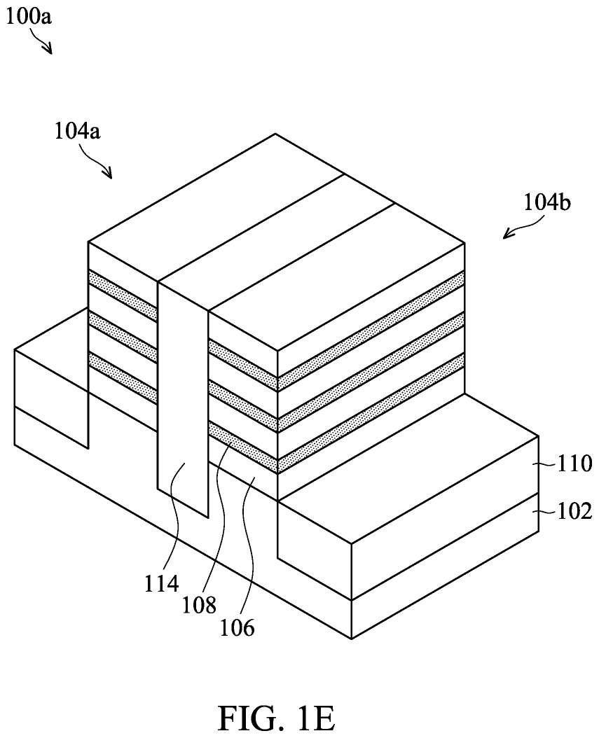

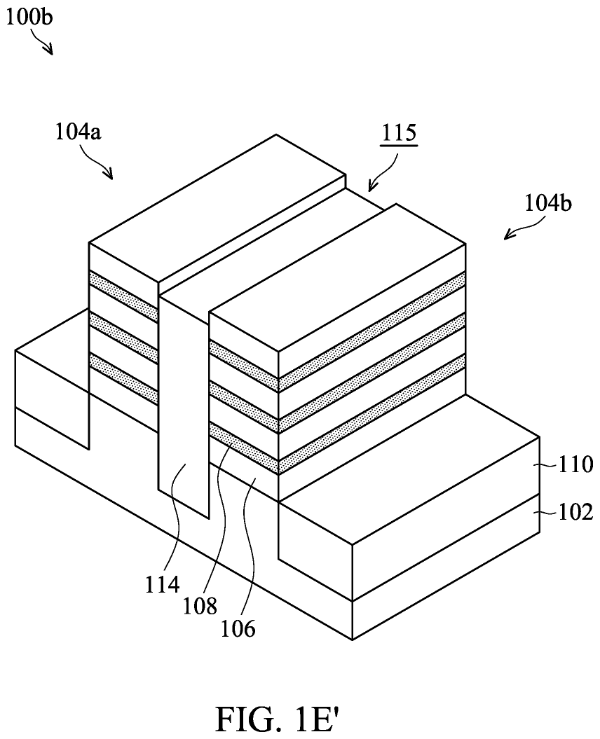

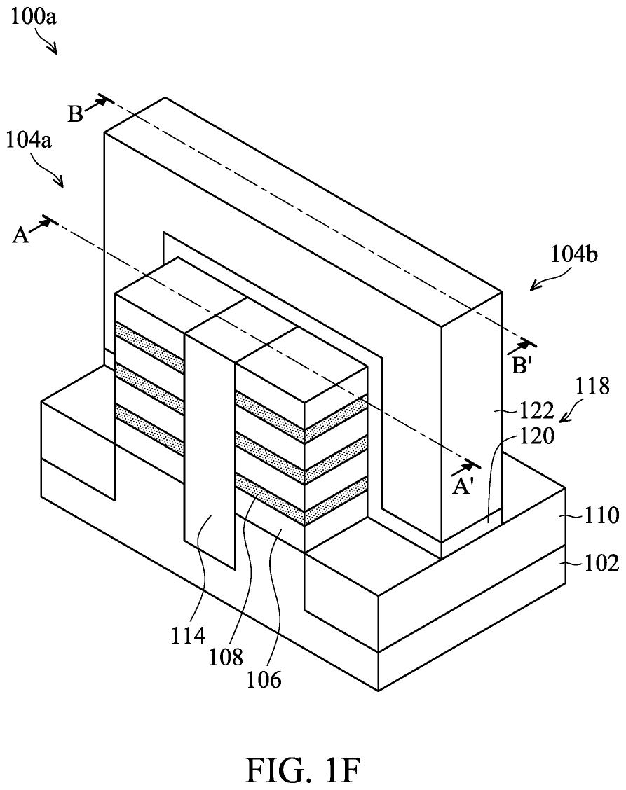

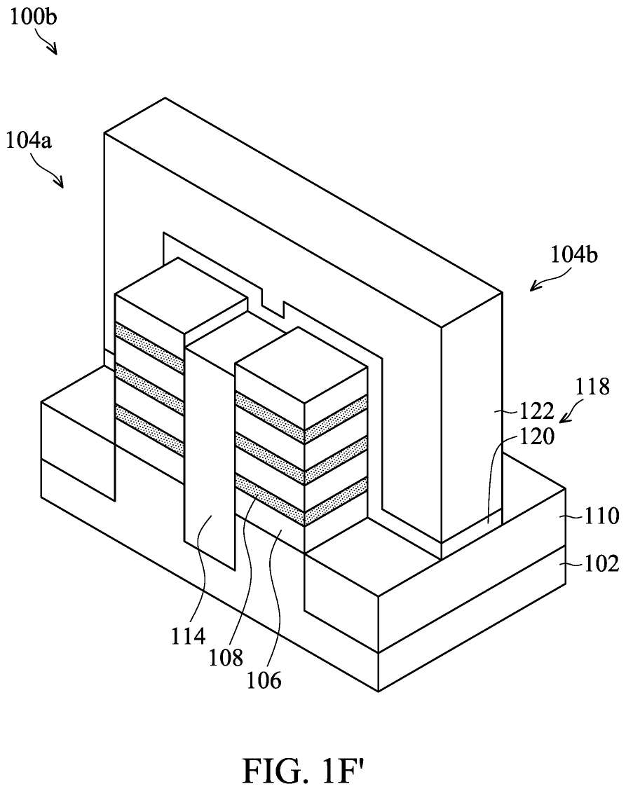

FIGS. 1A to 1F show perspective views of intermediate stages of manufacturing a semiconductor structure 100a in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiments, the first semiconductor layers 106 and the second semiconductor layers 108 independently include silicon (Si), germanium (Ge), silicon germanium (Si₁₋ₓGeₓ, 0.1<x<0.7, the value x is the atomic percentage of germanium (Ge) in the silicon germanium), indium arsenide (InAs), indium gallium arsenide (InGaAs), indium antimonide (InSb), or another applicable material.

The first semiconductor layers 106 and the second semiconductor layers 108 are made of different materials having different lattice constant. In some embodiments, the first semiconductor layer 106 is made of silicon (Si), and the second semiconductor layer 108 is made of silicon germanium (Si₁₋ₓGex, 0.1<x<0.7). In some other embodiments, the first semiconductor layer 106 is made of silicon germanium (Si₁₋ₓGex, 0.1<x<0.7), and the second semiconductor layer 108 is made of silicon (Si).

It should be noted that although four first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

As shown in FIG. 1A, after the first semiconductor material layers 106 and the second semiconductor material layers 108 are formed as a semiconductor material stack over the substrate 102, the semiconductor material stack is patterned to form a first stack structure 104a and a second stack structure 104b, in accordance with some embodiments.

In some embodiments, the patterning process includes forming a mask structure (not shown) over the semiconductor material stack, and etching the semiconductor material stack and the underlying substrate 102 through the mask structure. In some embodiments, the mask structure is a multilayer structure including a pad oxide layer and a nitride layer formed over the pad oxide layer. The pad oxide layer may be made of silicon oxide, which is formed by thermal oxidation or chemical vapor deposition (CVD), and the nitride layer may be made of silicon nitride, which is formed by chemical vapor deposition (CVD), such as low-temperature chemical vapor deposition (LPCVD) or plasma-enhanced CVD (PECVD).

As shown in FIG. 1B, after the first stack structure 104a and the second stack structure 104b are formed, an isolation material 109 is formed around the first stack structure 104a and the second stack structure 104b, in accordance with some embodiments.

In some embodiments, the isolation material 109 is made of a low-k dielectric material with K value lower than 5. In some embodiments, the isolation material 109 is made of silicon oxide, silicon nitride, silicon oxynitride (SiON), another suitable insulating material, or a combination thereof. The isolation material 109 may be a flowable dielectric material that can “flow” during deposition to fill voids in a gap. The isolation material 109 may be formed using a high-density plasma chemical vapor deposition (HDP-CVD), a flowable CVD (FCVD), combinations of these, or the like.

In some embodiments, a dielectric liner (not shown) is formed before the isolation material 109 is formed, and the dielectric liner is made of silicon nitride and the isolation structure formed over the dielectric liner is made of silicon oxide.

Afterwards, as shown in FIG. 1C, the top portion of the isolation material 109 is removed until the topmost first semiconductor layers 106 of the first stack structure 104a and the second stack structure 104b are exposed, in accordance with some embodiments. In some embodiments, the top portion of the isolation material 109 is removed by a planarization process, such as CMP or an etch-back process.

Next, as shown in FIG. 1D, a photoresist layer 111 is formed over the first stack structure 104a, the second stack structure 104b and the isolation material 109, in accordance with some embodiments. Next, the photoresist layer 111 is patterned to form a patterned photoresist layer 111. The photoresist layer 111 covers the space between the first stack structure 104a and the second stack structure 104b.

Afterwards, as shown in FIG. 1E, the portions of the isolation material 109 which are not covered by the photoresist layer 111 are removed, in accordance with some embodiments. The portions of the isolation material 109 are removed by an etching process. As a result, a dielectric wall 114 and the isolation structure 110 are obtained. In some embodiments, the dielectric wall 114 and the isolation structure 110 are formed simultaneously. The dielectric wall 114 and an isolation structure 110 are made of the same material. In some embodiments, the dielectric wall 114 and an isolation structure 110 includes a low-k dielectric material with K value smaller than 5. The top surface of the dielectric wall 114 is substantially leveled with the top surface of the topmost first semiconductor layer 106.

The dielectric wall 114 is between and in direct contact with the first stack structure 104a and the second stack structure 104b. The dielectric wall 114 protrudes from the isolation structure 110. The isolation structure 110 is configured to electrically isolate active regions (e.g. the first stack structure 104a or the second stack structure 104b) of the semiconductor structure 100a and is also referred to as shallow trench isolation (STI) feature in accordance with some embodiments.

Afterwards, as shown in FIG. 1F, dummy gate structure 118 is formed across the first stack structure 104a and the second stack structure 104b and extends over the isolation structure 110, in accordance with some embodiments. The first stack structure 104a and the second stack structure 104b extends along the first direction, such as the X-axis, and the dummy gate structure 118 extends along the second direction, such as the Y-axis.

The dummy gate structure 118 may be used to define the source/drain (S/D) regions and the channel regions of the resulting semiconductor structure 100a. In some embodiments, the dummy gate structure 118 includes a dummy gate dielectric layer 120 and a dummy gate electrode layer 122.

In some embodiments, the dummy gate dielectric layer 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 120 is formed using thermal oxidation, chemical vapor deposition (CVD), atomic vapor deposition (ALD), physical vapor deposition (PVD), another suitable method, or a combination thereof. In some embodiments, the dummy gate electrode layer 122 includes polycrystalline-silicon (poly-Si), poly-crystalline silicon-germanium (poly-SiGe), metallic nitrides, metallic silicides, metals, or a combination thereof. In some embodiments, the dummy gate electrode layer 122 is formed using chemical vapor deposition (CVD), physical vapor deposition (PVD), or a combination thereof.

FIGS. 1D′ to 1F′ show perspective views of intermediate stages of manufacturing a semiconductor structure 100b, in accordance with some embodiments. The semiconductor structure 100b of FIG. 1D′ includes elements that are similar to, or the same as, elements of the semiconductor structure 100a of FIG. 1D. The difference between FIG. 1D′ and FIG. 1D is that no photoresist layer is formed over the dielectric wall 114.

As shown in FIG. 1E′, since the space between the first stack structure 104a and the second stack structure 104b is smaller than the space outside of the first stack structure 104a or the second stack structure 104b, the etching rate of the isolation material 109 between the first stack structure 104a and the second stack structure 104b is smaller than the etching rate of the isolation material 109 outside of the first stack structure 104a or the second stack structure 104b. Therefore, the dielectric wall 114 between the first stack structure 104a and the second stack structure 104b is higher than the isolation structure 110. In addition, since no photoresist layer is directly formed on the dielectric wall 114, the top portion of the dielectric wall 114 is removed to form a recess 115. The top surfaces of the first stack structure 104a and the second stack structure 104b are higher than the top surface of the dielectric wall 114.

Next, as shown in FIG. 1F′, the dummy gate structure 118 is formed across the first stack structure 104a and the second stack structure 104b and extends over the isolation structure 110, in accordance with some embodiments. A portion of the dummy gate structure 118 is formed into the recess 115 directly above the dielectric wall 114.

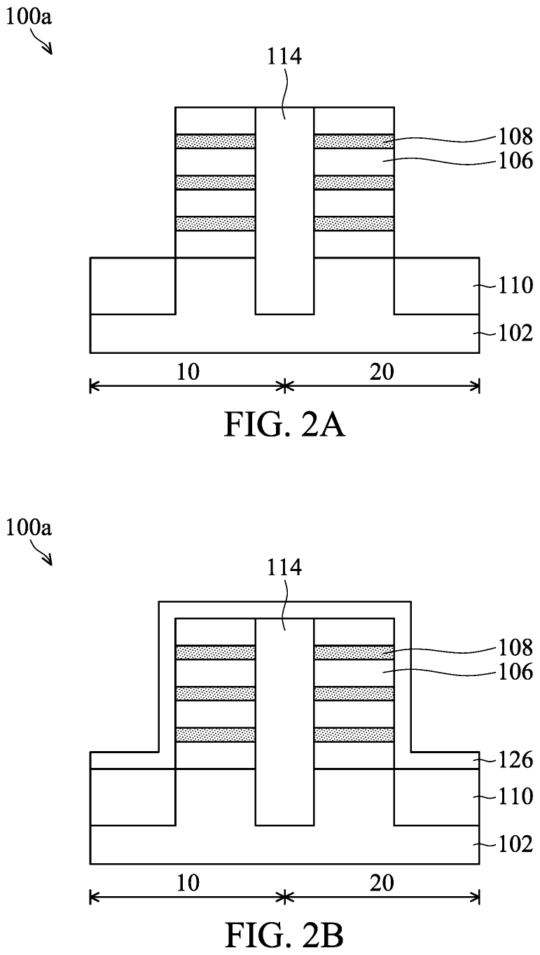

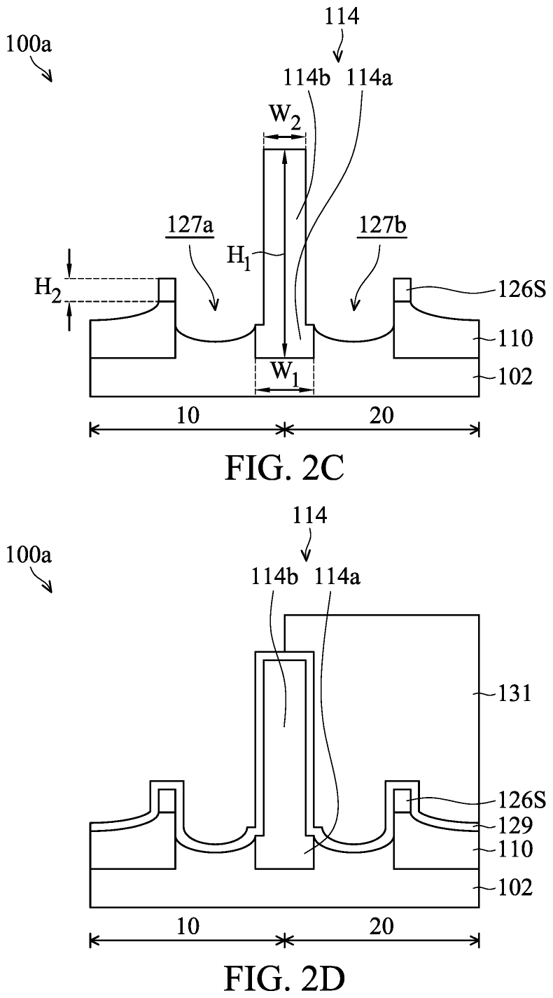

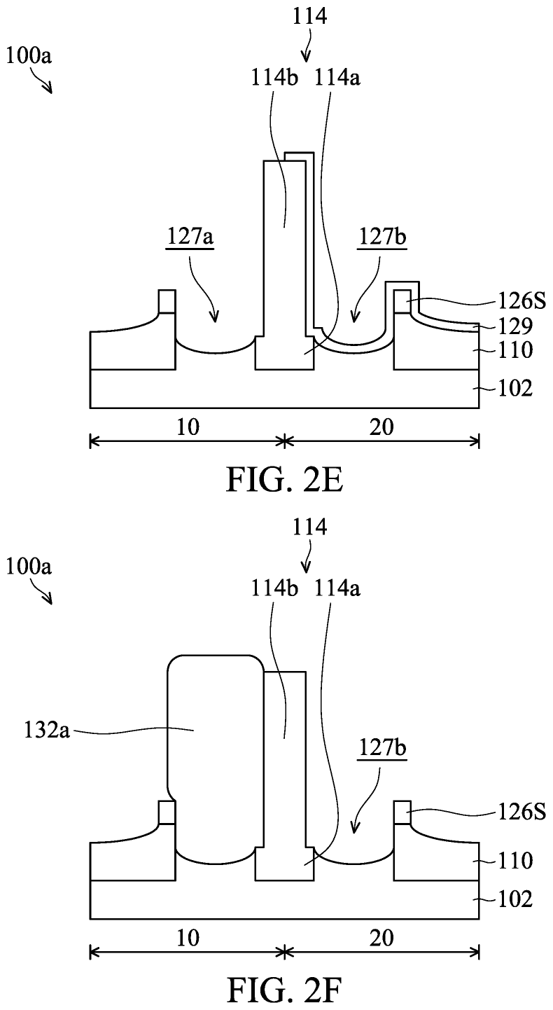

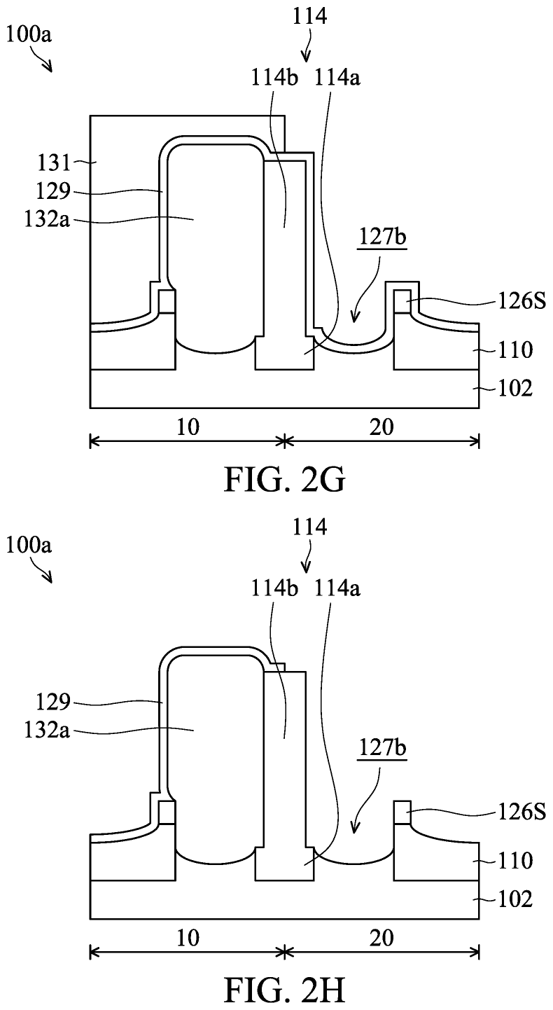

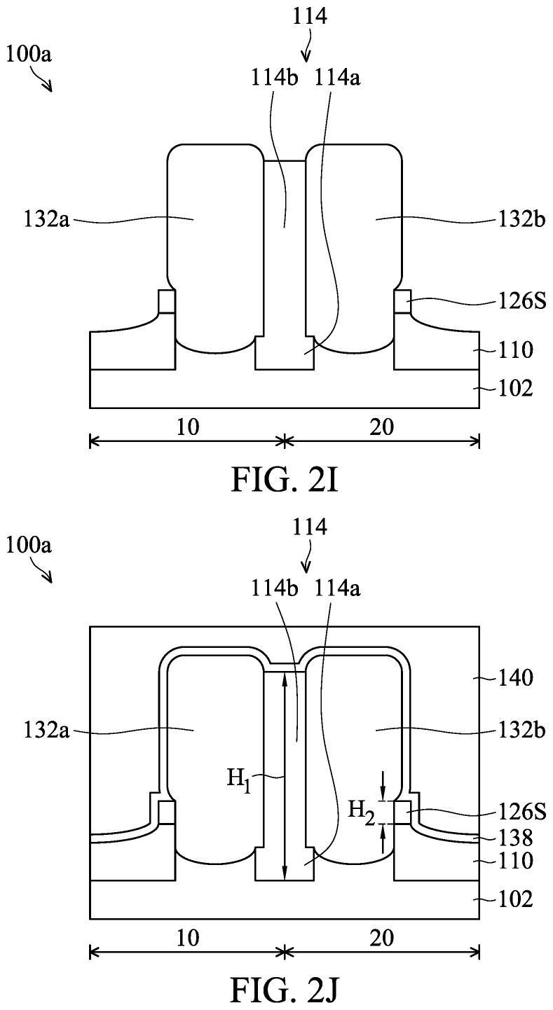

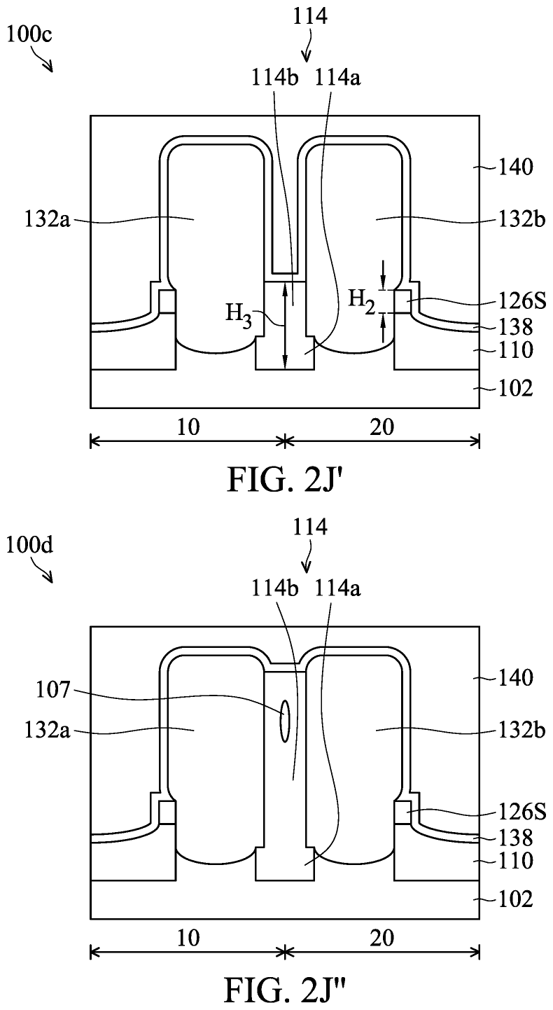

FIGS. 2A to 2J show cross-sectional representations of various stages of manufacturing the semiconductor structure 100a shown along line A-A′ in FIG. 1F, in accordance with some embodiments. More specifically, FIG. 2A shows the cross-sectional representation shown along line A-A′ in FIG. 1F, in accordance with some embodiments. FIG. 2A shows an S/D region.

As shown in FIG. 2A, the substrate 102 includes a first region 10 and a second region 20. The first stack structure 104a is formed in the first region 10, and the second stack structure 104b is formed in the second region 20. The dielectric wall 114 is between and in direct contact with the first stack structure 104a and the second stack structure 104b. The bottom surface of the dielectric wall 114 is substantially leveled with the bottom surface of the isolation structure 110. The top surface of the dielectric wall 114 is substantially leveled with the top surface of the topmost first semiconductor layer 106.

Next, as shown in FIG. 2B, a spacer layer 126 is formed along and covering opposite sidewalls of the dummy gate structure 118 and are formed along and covering opposite sidewalls of the source/drain(S/D) regions of the first stack structure 104a and the second stack structure 104b and the dielectric wall 114, in accordance with some embodiments. The spacer layer 126 may be configured to constrain a lateral growth of subsequently formed source/drain (S/D) structure (formed later) and support the first stack structure 104a and the second stack structure 104b.

In some embodiments, the spacer layer 126 is made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the spacer layer 126 is formed by chemical vapor deposition (CVD), atomic vapor deposition (ALD), physical vapor deposition (PVD), another suitable method, or a combination thereof.

Afterwards, as shown in FIG. 2C, a portion of the spacer layer 126 is removed to form a shortened spacer layer 126S, and then portions of the first stack structure 104a and the second stack structure 104b are removed, in accordance with some embodiments. As a result, a first S/D recess 127a and a second S/D recess 127b are formed, and the top surfaces of the substrate 102 are exposed by the first S/D recess 127a and the second S/D recess 127b.

Some portions of the first stack structure 104a and the second stack structure 104b are recessed to form curved top surfaces. The curved top surfaces of the first stack structure 104a and the second stack structure 104b are lower than the top surface of the isolation structure 110, and lower than the top surface of the shortened spacer layer 126S. In some embodiments, the first stack structure 104a and the second stack structure 104b are recessed by performing an etching process. The etching process may be an anisotropic etching process, such as dry plasma etching, and the dummy gate structure 118 and the shortened spacer layer 126S are used as etching masks during the etching process.

When the top portion of the spacer layer 126 is removed to form the shortened spacer layer 126S, the portions of the dielectric wall 114 are simultaneously removed. The dielectric wall 114 has a bottom portion 114a and a top portion 114b, and the bottom portion 114b is wider than the top portion 114a. In some embodiments, the dielectric wall 114 has a reversed T-shapes structure.

The dielectric wall 114 has a first height H₁ along a vertical direction, and the shortened spacer layer 126S has a second height H₂ along the vertical direction. In some embodiments, the first height H₁ of the dielectric wall 114 is greater than the second height H₂ of the shortened spacer layer 126S. The top surface of the dielectric wall 114 is higher than the top surface of the spacer layer 126S. The bottom portion 114a of the dielectric wall 114 has a first width W₁ along the second direction (e.g. Y-axis), and the top portion 114b of the dielectric wall 114 has a second width W₂. along the second direction (e.g. Y-axis). The first width W₁ is greater than the second width W₂.

Afterwards, as shown in FIG. 2D, a hard mask layer 129 is formed on the shortened spacer layer 126S, the dielectric wall 114, the first stack structure 104a, the second stack structure 104b, and the isolation structure 110, in accordance with some embodiments. Next, a photoresist layer 131 is formed over a portion of the hard mask layer 129. The photoresist layer 131 is patterned to form a patterned photoresist layer 131 to transfer the pattern to the hard mask layer 129. The patterned photoresist layer 131 is formed in the second region 20.

The spacer layer 126 has a high etching selectivity with respect to the hard mask layer 129. In addition, the dielectric wall 114 has a high etching selectivity with respect to the hard mask layer 129. When the hard mask layer 129 is removed, the spacer layer 126 and the dielectric wall 114 are rarely removed. In some embodiments, the hard mask layer 129 is made of nitride or oxide, such as silicon nitride or aluminum oxide (Al₂O₃) or another applicable material. In some embodiments, the hard mask layer 129 is formed by chemical vapor deposition (CVD), atomic vapor deposition (ALD), physical vapor deposition (PVD), another suitable method, or a combination thereof.

Afterwards, as shown in FIGS. 2E, a portion of the hard mask layer 129 in the first region 10 which is not coved by the photoresist layer 131 is removed to expose the first S/D recess 127a, and then the photoresist layer 131 is removed, in accordance with some embodiments. The remaining hard mask layer 129 is still in the second region 20.

Next, as shown in FIGS. 2F, a first S/D structure 132a is formed in the first S/D recess 127a in the first region 10, in accordance with some embodiments. The first S/D structure 132a extends above the top surface of dielectric wall 114. In addition, a portion of the first S/D structure 132a is in direct contact with the dielectric wall 114. More specifically, the portion of the first S/D structure 132a is in direct contact with the sidewall of the dielectric wall 114.

In some embodiments, the first S/D structures 132a is made of any applicable material, such as Ge, Si, GaAs, AlGaAs, SiGe, GaAsP, SiP, SiC, SiCP, or a combination thereof. In some embodiments, the first S/D structure 132a is formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof.

In some embodiments, the first S/D structure 132a is in-situ doped during the epitaxial growth process. For example, the first S/D structure 132a may be the epitaxially grown SiGe doped with boron (B). For example, the first S/D structure 132a may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the first S/D structures 132a are doped in one or more implantation processes after the epitaxial growth process.

Afterwards, as shown in FIG. 2G, the hard mask layer 129 is again formed on the shortened spacer layer 126S, the dielectric wall 114, the isolation structure 110 and the first S/D structure 132a, in accordance with some embodiments. Next, the photoresist layer 131 is formed over a portion of the hard mask layer 129 in the first region 10, and the photoresist layer 131 is patterned to form a patterned photoresist layer 131. The patterned photoresist layer 131 is in the first region 10.

Next, as shown in FIG. 2H, a portion of the hard mask layer 129 is removed to expose the second S/D recess 127b in the second region 20, in accordance with some embodiments. The remaining hard mask layer 129 is used to protect the first S/D structure 132a. Next, the photoresist layer 131 is removed.

Afterwards, as shown in FIG. 2I, a second S/D structure 132b is formed in the second S/D recess 127b in the second region 20, in accordance with some embodiments. Next, the hard mask layer 129 is removed after the second S/D structure 132b is formed. In addition, the second S/D structure 132b is in direct contact with the dielectric wall 114. More specifically, the second S/D structure 132b is in direct contact with the sidewalls of the dielectric wall 114. The bottom surface of the dielectric wall 114 is lower than the bottom surface of the first S/D structure 132a.

In some embodiments, the second S/D structures 132b is made of any applicable material, such as Ge, Si, GaAs, AlGaAs, SiGe, GaAsP, SiP, SiC, SiCP, or a combination thereof. In some embodiments, the second S/D structure 132b is formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof.

In some embodiments, the second S/D structure 132b is in-situ doped during the epitaxial growth process. For example, the second S/D structure 132b may be the epitaxially grown SiGe doped with boron (B). For example, the second S/D structure 132b may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the second S/D structures 132b are doped in one or more implantation processes after the epitaxial growth process.

Next, as shown in FIG. 2J, after the first S/D structure 132a and second S/D structures 132b are formed, a contact etch stop layer (CESL) 138 is conformally formed to cover the S/D structures 136 and an interlayer dielectric (ILD) layer 140 is formed over the contact etch stop layers 138, in accordance with some embodiments.

It should be noted that the space between the first S/D structure 132a and the second S/D structure 132b is filled with the CESL 138. The CESL 138 is in direct contact with the top surface of the dielectric wall 114.

In some embodiments, the CESL 138 is made of a dielectric materials, such as silicon nitride, silicon oxide, silicon oxynitride, another suitable dielectric material, or a combination thereof. The dielectric material for the CESL 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the CESL 138 and the ILD layer 140 are deposited, a planarization process such as CMP or an etch-back process may be performed until the gate electrode layers 120 of the dummy gate structures 118 are exposed.

It should be noted that the dielectric wall 114 includes a low-k dielectric material with K value smaller than 5. The dielectric wall 114 with low-k material can reduce the capacitance of the semiconductor structure 100a, and therefore the performance of the semiconductor structure 100a is improved.

Furthermore, when forming the dielectric wall, a void or seam may be formed in the dielectric wall. The void or seam may case current leakage issue between the gate structure and the S/D contact structure. In order to reduce the current leakage issue, the dielectric wall 114 is formed by a flowable material. Therefore, the dielectric wall may be void free or seam free.

FIG. 2J′ shows a cross-sectional view of a semiconductor structure 100c, in accordance with some embodiments. The semiconductor structure 100c of FIG. 2J′ includes elements that are similar to, or the same as, elements of the semiconductor structure 100a of FIG. 2J. The difference between FIG. 2J′ and FIG. 2J is that the dielectric wall 114 in FIG. 2J′ is lower than the dielectric wall 114 in FIG. 2J. The dielectric wall 114 in FIG. 2J′ has a third height H₃ along the vertical direction, and the third height H₃ is smaller than the first height H₁ (FIG. 2J).

In some embodiments, the top surface of the dielectric wall 114 is higher than the top surface of the shortened spacer layer 126S. In some other embodiments, the top surface of the dielectric wall 114 is smaller than, or substantially equal to the top surface of the shortened spacer layer 126S.

FIG. 2J″ shows a cross-sectional view of a semiconductor structure 100d, in accordance with some embodiments. The semiconductor structure 100d of FIG. 2J″ includes elements that are similar to, or the same as, elements of the semiconductor structure 100a of FIG. 2J. The difference between FIG. 2J″ and FIG. 2J is that a void 107 is formed in the dielectric wall 114.

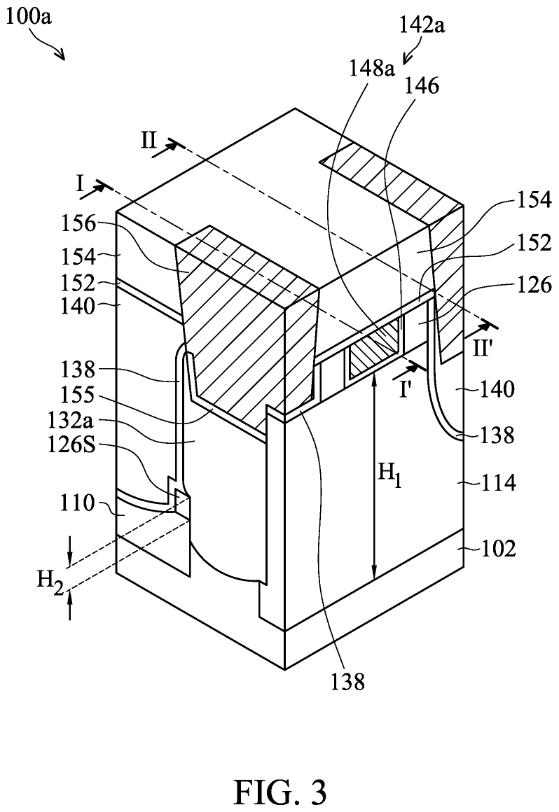

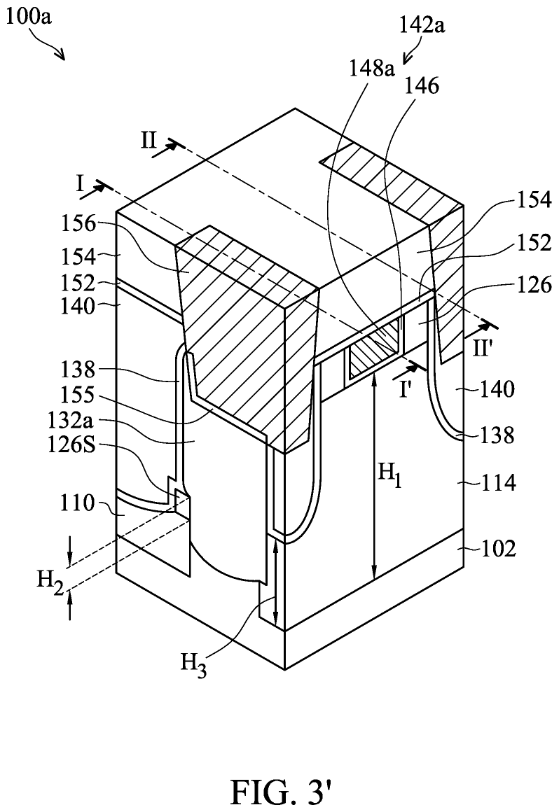

FIG. 3 shows a perspective view of the semiconductor structure 100a after the step of FIG. 2J, in accordance with some embodiments. More specifically, FIG. 2J shows the cross-sectional representation shown along line I-I′ in FIG. 3, in accordance with some embodiments.

As shown in FIG. 3, an etching stop layer 152 is formed over the ILD layer 140, and a first gate structure 142a (formed later), in accordance with some embodiments. Next, an ILD layer 154 is formed over the etching stop layer 152. Afterwards, a portion of the ILD layer 154, a portion of the etching stop layer 152, a portion of the first S/D structure 152a, and a portion of the second S/D structure 152b are removed to form a contact opening (not shown). The top surfaces of the first S/D structure 152a and the top surface of the second S/D structure 152b are exposed by the contact opening. Next, a silicide layer 155 and an S/D contact structure 156 are formed over the first S/D structure 132a and the second S/D structure 132b.

In some embodiments, the contact openings are formed through the CESL 138, the ILD layer 140, the etching stop layer 152 and the ILD layer 154 to expose the top surfaces of the first S/D structures 132a, and then the silicide layer 155 and the S/D contact structure 156 are formed in the contact openings. The contact openings may be formed using a photolithography process and an etching process. In addition, some portions of the first S/D structures 132a exposed by the contact openings may also be etched during the etching process.

After the contact openings are formed, a silicide layer 155 may be formed by forming a metal layer over the top surface of the first S/D structures 132a and annealing the metal layer so the metal layer reacts with the first S/D structures 132a to form the silicide layer 155. The unreacted metal layer may be removed after the silicide layers 155 are formed.

The S/D contact structure 156 may include a barrier layer and a conductive layer. In some embodiments, the barrier layer is made of titanium (Ti), titanium nitride (TiN), tantalum (Ta), tantalum nitride (TaN), or another applicable material. In some embodiments, the barrier layer is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. In some embodiments, the conductive layer is made of tungsten (W), ruthenium (Ru), molybdenum (Mo), or the like. In some embodiments, the conductive layer is formed by performing a deposition process, such as chemical vapor deposition (CVD), physical vapor deposition, (PVD), atomic layer deposition (ALD), or other applicable processes.

FIG. 3′ shows a perspective view of the semiconductor structure 100c, after FIG. 2J′, in accordance with some embodiments. The semiconductor structure 100c of FIG. 3′ includes elements that are similar to, or the same as, elements of the semiconductor structure 100a of FIG. 3. The difference between FIG. 3′ and FIG. 3 is that the dielectric wall 114 directly below the S/D contact structure 156 in FIG. 3′ is lower than the dielectric wall 114 directly below the S/D contact structure 156 in FIG. 3.

The dielectric wall 114 has a first portion directly below the first gate structure 142a, and a second portion directly below the S/D contact structure 156. The first portion has a first height H₁ along the vertical direction, and the second portion has a third height H₃ along the vertical direction. The first height H₁ is greater than the third height H₃.

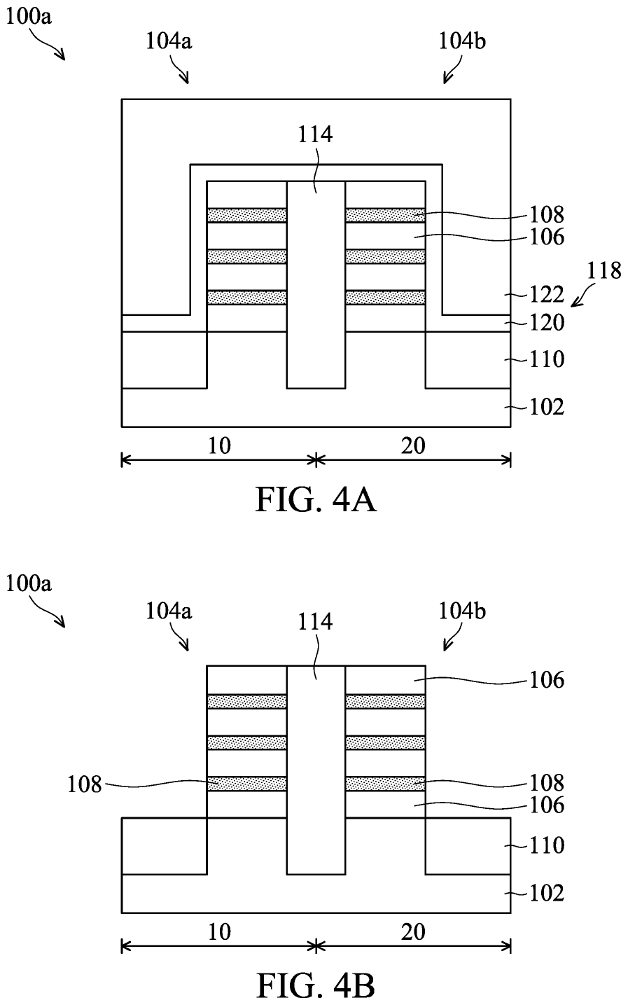

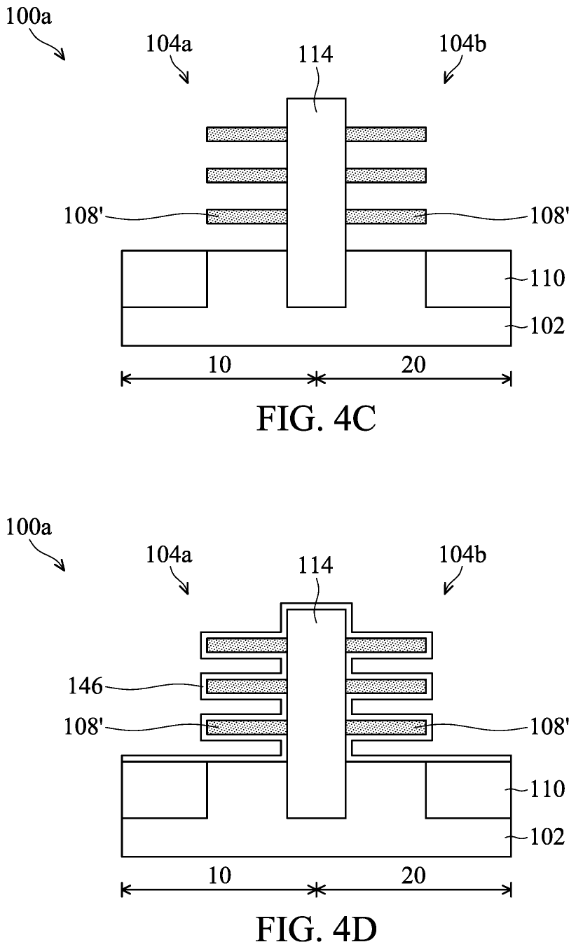

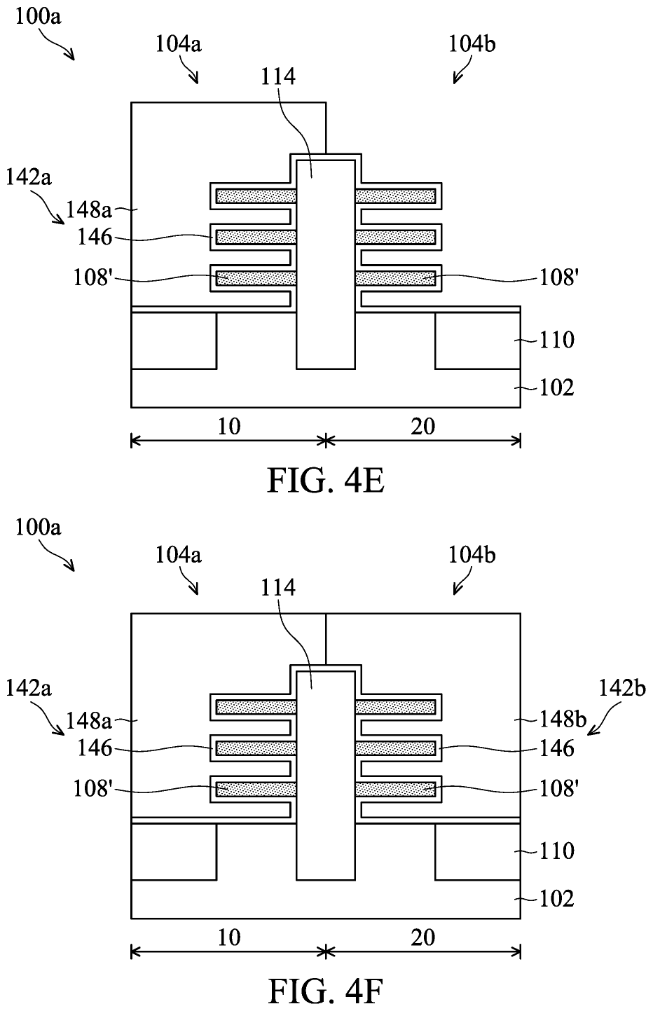

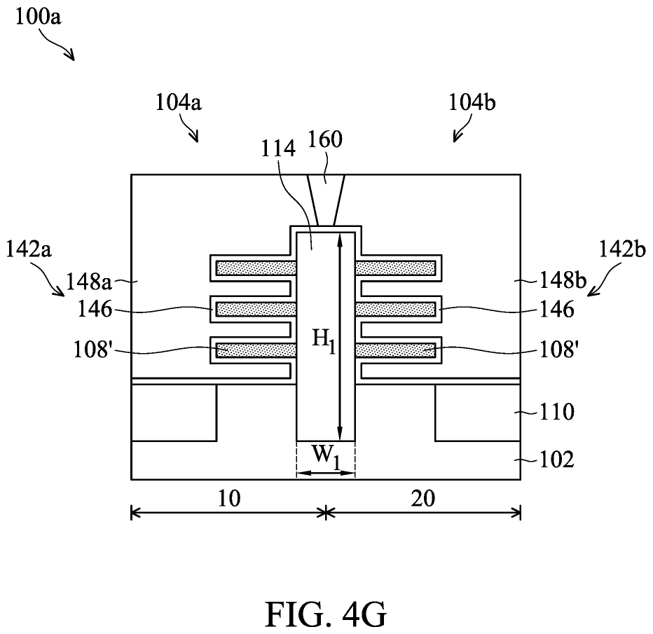

FIGS. 4A to 4G show cross-sectional representations of various stages of manufacturing the semiconductor structure 100a shown along line B-B′ in FIG. 1F, in accordance with some embodiments. More specifically, FIG. 4A shows the cross-sectional representation shown along line B-B′ in FIG. 1F, in accordance with some embodiments. FIG. 4A shows a gate structure region. FIG. 4F shows the cross-sectional representation shown along line II-II′ in FIG. 3, in accordance with some embodiments.

As shown in FIG. 4A, the dummy gate structure 118 is formed over the first stack structure 104a, the second stack structure 104b, the dielectric wall 114 and the isolation structure 110, in accordance with some embodiments.

Next, as shown in FIG. 4B, the dummy gate structure 118 is removed to expose the first stack structure 104a and the second stack structure 104b, in accordance with some embodiments. As a result, the dielectric wall 114 is exposed. It should be noted that, the dielectric wall 114 along line B-B′ in FIG. 1F, is directly below the dummy gate structure 118 and protected by the dummy gate structure 118, it is not removed when the process for forming the first S/D structure 132a and the second S/D structure 132b.

The removal process may include one or more etching processes. For example, when the dummy gate electrode layer 122 is polysilicon, a wet etchant such as a tetramethylammonium hydroxide (TMAH) solution may be used to selectively remove the dummy gate electrode layer 122. Afterwards, the dummy gate dielectric layer 120 may be removed using a plasma dry etching, a dry chemical etching, and/or a wet etching.

Next, as shown in FIG. 4C, the first semiconductor material layers 106 are removed to form nanostructures 108′ with the second semiconductor material layers 108, in accordance with some embodiments. The dielectric wall 114 is between the first nanostructures 108′ of the first stack structure 104a in the first region 10 and the nanostructures 108′ of the second stack structure 104b in the second region 20. The nanostructures 108′ are connected to the dielectric wall 114. The top surface of the dielectric wall 114 is higher than the top surface of the topmost nanostructure 108′.

The first S/D structure 132a and the second S/D structure 132b are attached to and connected to the nanostructures 108′.

The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

Next, as shown in FIG. 4D, after the nanostructures 108′ are formed, a gate dielectric layer 146 is formed to surround the nanostructures 108′ and over the isolation structure 110, in accordance with some embodiments. Furthermore, an interfacial layer (not shown) may be formed before forming the gate dielectric layer 146. The gate dielectric layer 146 is in direct contact with the dielectric wall 114.

In some embodiments, the interfacial layer is oxide layer formed around the nanostructures 108′. In some embodiments, the interfacial layer is formed by performing a thermal process. In some embodiments, the gate dielectric layers 146 are formed over the interfacial layers, so that the nanostructures 108′ are surrounded (e.g. wrapped) by the gate dielectric layers 146. In some embodiments, the gate dielectric layers 146 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, another suitable high-k dielectric material, or a combination thereof. In some embodiments, the gate dielectric layers 146 are formed using chemical vapor deposition (CVD), atomic layer deposition (ALD), another applicable method, or a combination thereof.

Next, as shown in FIG. 4E, a first gate electrode layer 148a is formed in the first region 10 to surround the nanostructures 108′ of the first stack structure 104a, in accordance with some embodiments. The first gate electrode layer 148a formed across the nanostructures 108′ (shown in FIG. 3). The first gate structure 142a is constructed by the interfacial layer (not shown), the gate dielectric layer 146, and the first gate electrode layer 148a.

The first gate structure 142a wraps around the nanostructures 108′ to form gate-all-around transistor structures. In some embodiments, the first gate electrode layer 148a is formed on the gate dielectric layer 146. In some embodiments, the first gate electrode layer 148a is made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the first gate electrode layer 148a is formed using chemical vapor deposition (CVD), atomic layer deposition (ALD), electroplating, another applicable method, or a combination thereof.

Other conductive layers, such as work function metal layers, may also be formed in the first gate structure 142a, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

Next, as shown in FIG. 4F, a second gate electrode layer 148b is formed in the second region 20 to surround the nanostructures 108′, in accordance with some embodiments. A second gate structure 142b is constructed by the interfacial layer (not shown), the gate dielectric layer 146, and the second gate electrode layer 148b. The material of the second gate electrode layer 148b is different from that of the first gate electrode layer 148a. There is an interface between the first gate electrode layer 148a and the second gate electrode layer 148b.

The second gate structure 142b wraps around the nanostructures 108′ to form gate-all-around transistor structures. In some embodiments, the second gate electrode layer 148b is formed on the gate dielectric layer 146. In some embodiments, the second gate electrode layer 148b is made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the second gate electrode layer 148b is formed using chemical vapor deposition (CVD), atomic layer deposition (ALD), electroplating, another applicable method, or a combination thereof.

Next, as shown in FIG. 4G, a cut structure 160 is formed over the dielectric wall 114. The cut structure 160 is in direct contact with the gate dielectric layer 146, the first gate electrode layer 148a and the second gate electrode layer 148b. The cut structure 160 is used to protect the underlying layers from damage during the subsequent etching processes.

In some embodiments, the cut structure 160 is made of oxide, such as SiO₂, SiOCN, SiON, or the like. In some embodiments, the cut structure 160 is made of a high k dielectric material, such as HfO₂, ZrO₂, HfAlOₓ, HfSiOₓ, Al₂O₃, or the like. In some embodiments, the cut structure 160 is formed by performing ALD, CVD, PVD, other suitable process, or combinations thereof.

It should be noted that the dielectric wall 114 has a first portion in the gate region and the second portion in the S/D region. The first portion of the dielectric wall 114 is directly below the first gate structure 142a and the second gate structure 142b. The first portion of the dielectric wall 114 has the first width W₁ and the first height H₁ (shown in FIG. 4G). The second portion of the dielectric wall 114 has the second width W₂ (shown in FIGS. 2C and 2J) between the first S/D structure 132a and the second S/D structure 132b. The second width W₂ is smaller than the first width W₁. In other words, the first width W₁ is greater than the second width W₂.

In addition, the first height H₁ of the first portion of the dielectric wall 114 in the gate region is greater than the third height H₃ of the second portion of the dielectric wall 114 in the S/D region (shown in FIG. 2J′).

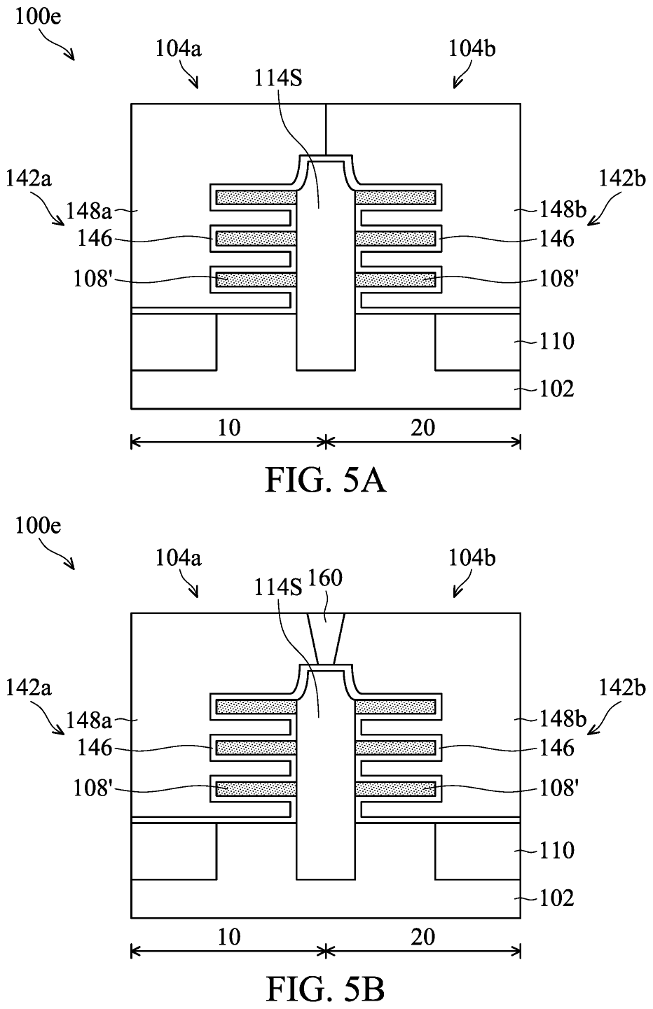

FIGS. 5A-5B shows a cross-sectional view of a semiconductor structure 100e, in accordance with some embodiments. The semiconductor structure 100e of FIG. 5A includes elements that are similar to, or the same as, elements of the semiconductor structure 100a of FIG. 4F. The difference between FIG. 5A and FIG. 4F is that the top portion of the dielectric wall 114 has been thinned to form a sharpened dielectric wall 114S.

Next, as shown in FIG. 5B, the cut structure 160 is formed over the sharped dielectric wall 114S. The cut structure 160 is in direct contact with the gate dielectric layer 146, the first gate electrode layer 148a and the second gate electrode layer 148b.

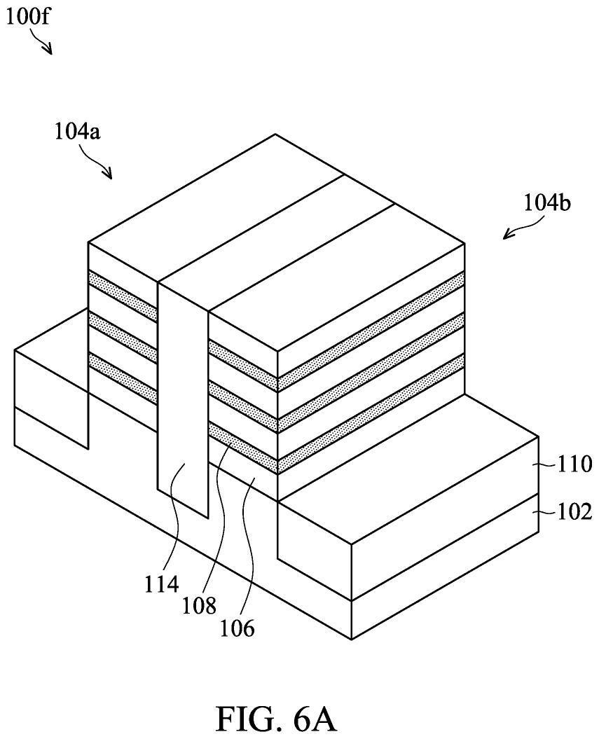

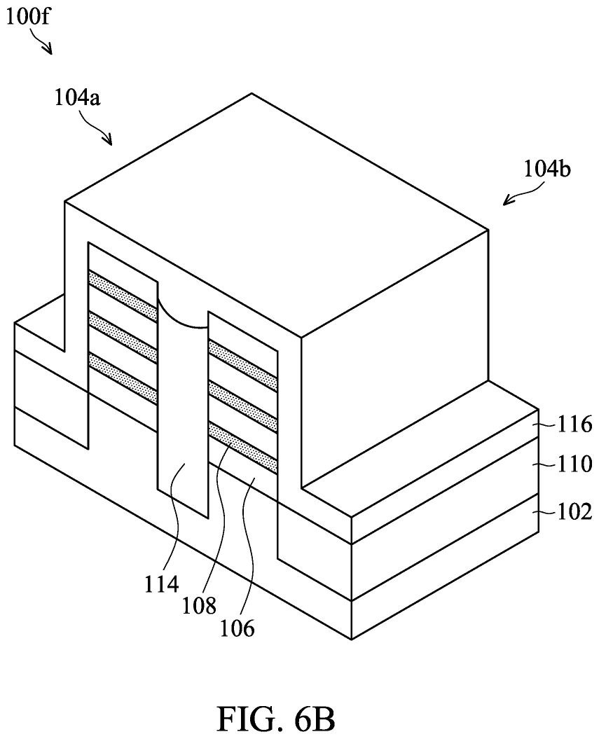

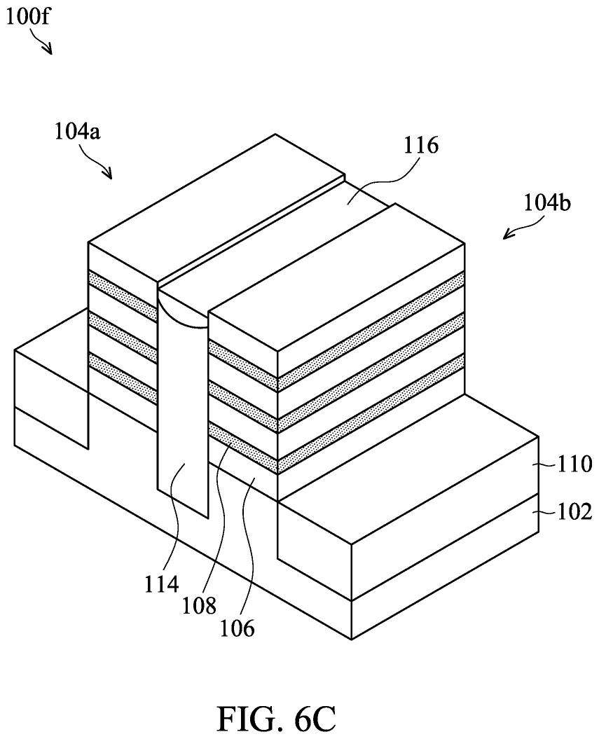

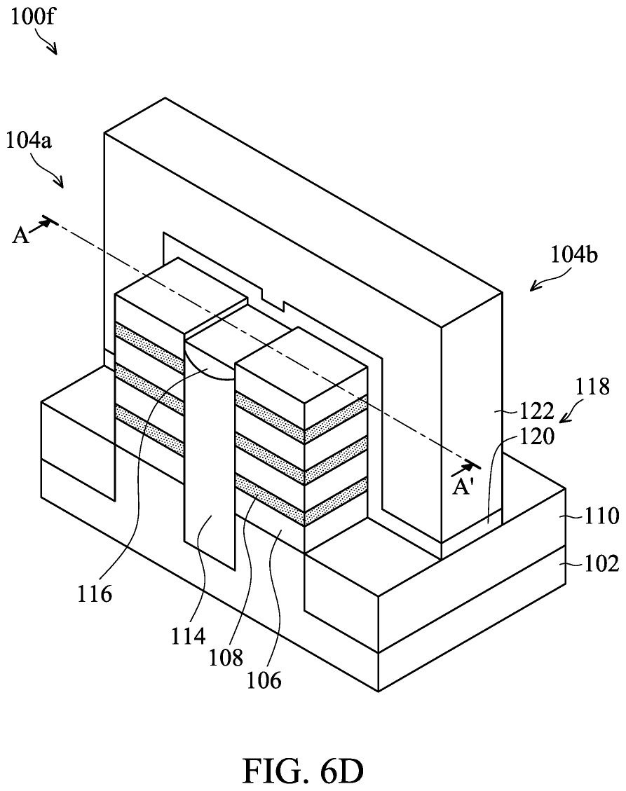

FIGS. 6A to 6D show perspective views of intermediate stages of manufacturing a semiconductor structure 100f, in accordance with some embodiments. The semiconductor structure 100f of FIG. 6A includes elements that are similar to, or the same as, elements of the semiconductor structure 100a of FIG. 1E.

Next, as shown in FIG. 6B, the top portion of the dielectric wall 114 is removed to form a recess, and a cap layer 116 is formed in the recess and the first stack structure 104a and the second stack structure 104b, in accordance with some embodiments.

In some embodiments, the cap layer 116 is made of high-k dielectric material with a K value greater than 6 (>6). The high-k dielectric material may include hafnium oxide (HfO₂), zirconium oxide (ZrO₂), aluminum oxide (Al₂O₃), hafnium alumina oxide (HfAlOx), hafnium silicon oxide (HfSiOx), hafnium silicon oxynitride, hafnium tantalum oxide (HfTaOx), hafnium titanium oxide (HfTiOx), hafnium zirconium oxide (HfZrOx), or the like. In some embodiments, the cap layer 116 is formed by a LPCVD process, plasma enhanced CVD (PECVD) process, high density plasma CVD (HDP-CVD) process, high aspect ratio process (HARP) process, flowable CVD (FCVD) process, atomic layer deposition (ALD) process, another suitable method, or a combination thereof.

Afterwards, as shown in FIG. 6C, a portion of the cap layer 116 is removed, in accordance with some embodiments. The remaining cap layer 116 is formed on the dielectric wall 114 and between the first stack structure 104a and the second stack structure 104b. The top surface of the cap layer 116 is lower than the top surface of the topmost first semiconductor layer 106.

Next, as shown in FIG. 6D, the dummy gate structure 118 is formed across the first stack structure 104a and the second stack structure 104b and extends over the isolation structure 110, in accordance with some embodiments. The first stack structure 104a and the second stack structure 104b extend along the first direction, such as the X-axis, and the dummy gate structure 118 extends along the second direction, such as the Y-axis.

The dummy gate structure 118 may be used to define the source/drain (S/D) regions and the channel regions of the resulting semiconductor structure 100a. In some embodiments, the dummy gate structure 118 includes the dummy gate dielectric layer 120 and the dummy gate electrode layer 122.

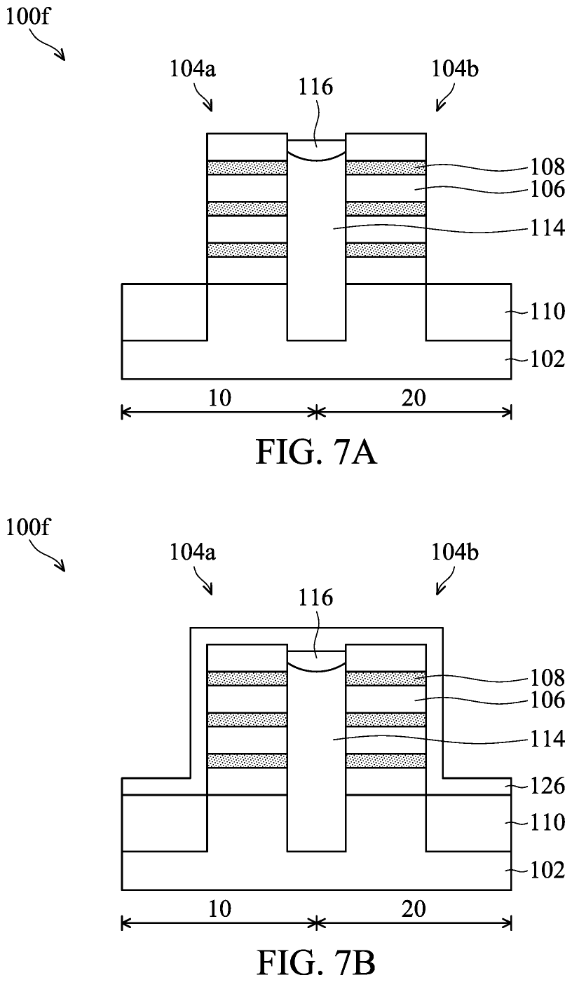

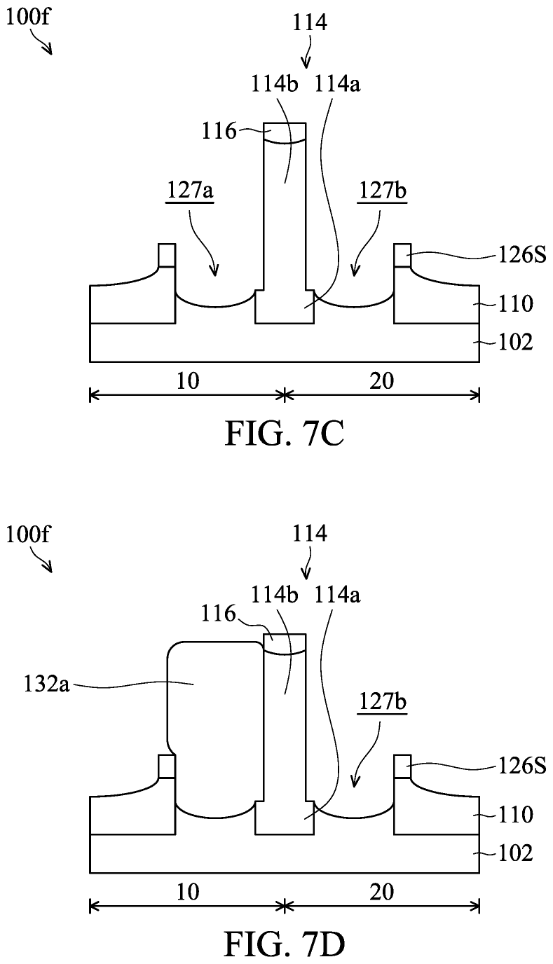

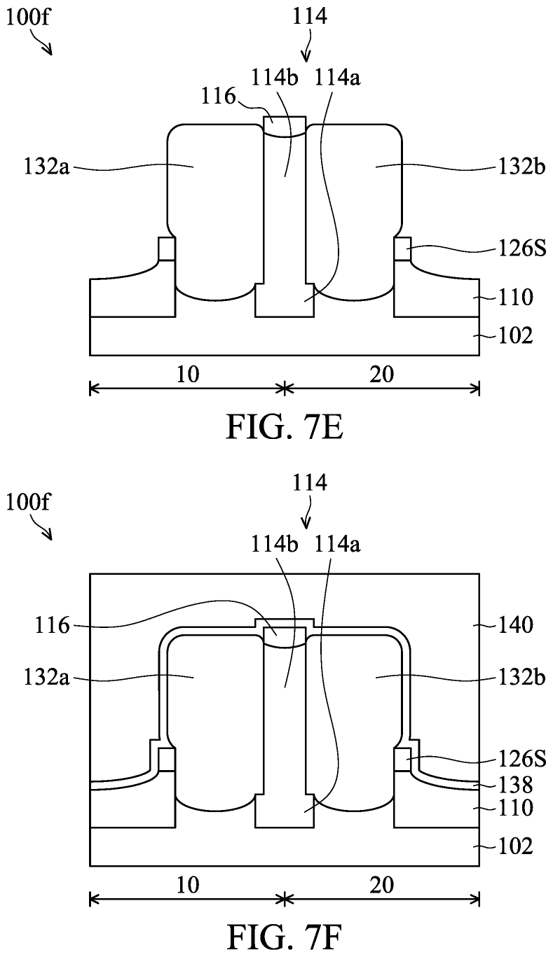

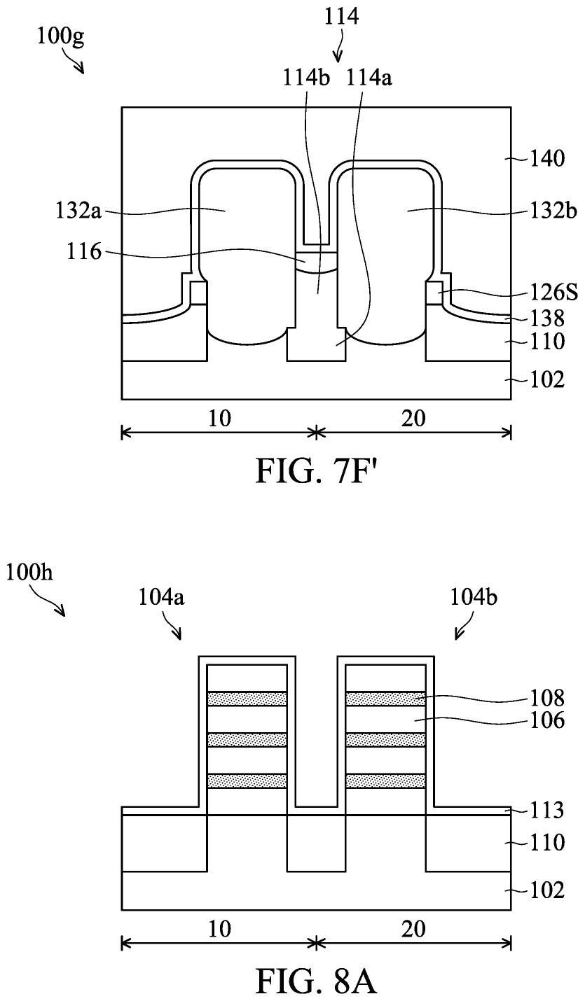

FIGS. 7A to 7F show cross-sectional representations of various stages of manufacturing the semiconductor structure 100f shown along line A-A′ in FIG. 6D, in accordance with some embodiments. FIG. 7A shows an S/D region.

As shown in FIG. 7A, the substrate 102 includes the first region 10 and the second region 20. The first stack structure 104a is formed in the first region 10, and the second stack structure 104b is formed in the second region 20. The dielectric wall 114 is between and in direct contact with the first stack structure 104a and the second stack structure 104b. The bottom surface of the dielectric wall 114 is substantially leveled with the bottom surface of the isolation structure 110. The top surface of the dielectric wall 114 is lower than the top surface of the topmost first semiconductor layer 106. The cap layer 116 is formed over the dielectric wall 114.

Next, as shown in FIG. 7B, the spacer layer 126 is formed along and covering opposite sidewalls of the dummy gate structure 118 and are formed along and covering opposite sidewalls of the source/drain(S/D) regions of the first stack structure 104a and the second stack structure 104b and the dielectric wall 114, in accordance with some embodiments. The spacer layer 126 may be configured to constrain a lateral growth of subsequently formed source/drain (S/D) structure (formed later) and support the first stack structure 104a and the second stack structure 104b.

In some embodiments, the spacer layer 126 is made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the spacer layer 126 is formed by chemical vapor deposition (CVD), atomic vapor deposition (ALD), physical vapor deposition (PVD), another suitable method, or a combination thereof.

Afterwards, as shown in FIG. 7C, a portion of the spacer layer 126 is removed to form the shortened spacer layer 126S, and then a portion of the first stack structure 104a and the second stack structure 104b is removed to form the first S/D recess 127a and the second S/D recess 127b, in accordance with some embodiments. As a result, the top surfaces of the substrate 102 are exposed by the first S/D recess 127a and the second S/D recess 127b.

When the top portion of the spacer layer 126 is removed to form the shortened spacer layer 126S, the portions of the dielectric wall 114 are simultaneously removed. The dielectric wall 114 has a bottom portion 114a and a top portion 114b, and the bottom portion 114b is wider than the top portion 114a. Since the cap layer 116 has a higher etching selectivity with respect the dielectric wall 114, the cap layer 116 is rarely removed when the portions of the dielectric wall 114 are removed. As a result, the dielectric wall 114 and the cap layer 116 construct an I-shaped structure.

Some portions of the first stack structure 104a and the second stack structure 104b are recessed to form curved top surfaces. The curved top surfaces of the first stack structure 104a and the second stack structure 104b are lower than the top surface of the isolation structure 110, and lower than the top surface of the shortened spacer layer 126S. In some embodiments, the first stack structure 104a and the second stack structure 104b are recessed by performing an etching process. The etching process may be an anisotropic etching process, such as dry plasma etching, and the dummy gate structure 118 and the shortened spacer layer 126S are used as etching masks during the etching process.

Next, as shown in FIG. 7D, the first S/D structure 132a is formed in the first S/D recess 127a in the first region 10, in accordance with some embodiments. The first S/D structure 132a is in direct contact with the dielectric wall 114. The first S/D structure 132a is in direct contact with the sidewall of the dielectric wall 114.

In some embodiments, the first S/D structures 132a is made of any applicable material, such as Ge, Si, GaAs, AlGaAs, SiGe, GaAsP, SiP, SiC, SiCP, or a combination thereof. In some embodiments, the first S/D structure 132a is formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof.

In some embodiments, the first S/D structure 132a is in-situ doped during the epitaxial growth process. For example, the first S/D structure 132a may be the epitaxially grown SiGe doped with boron (B). For example, the first S/D structure 132a may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the first S/D structures 132a are doped in one or more implantation processes after the epitaxial growth process.

Afterwards, as shown in FIG. 7E, the second S/D structure 132b is formed in the second S/D recess 127b in the second region 20, in accordance with some embodiments. The interface of the dielectric wall and the cap layer 116 is lower than the top surface of the first S/D structure 132a and the top surface of the second S/D structure 132b.

In some embodiments, the second S/D structures 132b is made of any applicable material, such as Ge, Si, GaAs, AlGaAs, SiGe, GaAsP, SiP, SiC, SiCP, or a combination thereof. In some embodiments, the second S/D structure 132b is formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof.

In some embodiments, the second S/D structure 132b is in-situ doped during the epitaxial growth process. For example, the second S/D structure 132b may be the epitaxially grown SiGe doped with boron (B). For example, the second S/D structure 132b may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the second S/D structures 132b are doped in one or more implantation processes after the epitaxial growth process.

Next, as shown in FIG. 7F, after the first S/D structure 132a and second S/D structures 132b are formed, the contact etch stop layer (CESL) 138 is conformally formed to cover the S/D structures 136 and the interlayer dielectric (ILD) layer 140 is formed over the contact etch stop layers 138, in accordance with some embodiments.

It should be noted that the space between the first S/D structure 132a and the second S/D structure 132b is filled with the CESL 138. The CESL 138 is in direct contact with the top surface of the dielectric wall 114.

In some embodiments, the CESL 138 is made of a dielectric materials, such as silicon nitride, silicon oxide, silicon oxynitride, another suitable dielectric material, or a combination thereof. The dielectric material for the CESL 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

FIG. 7F′ shows a cross-sectional view of a semiconductor structure 100f, in accordance with some embodiments. The semiconductor structure 100f of FIG. 7F′ includes elements that are similar to, or the same as, elements of the semiconductor structure 100f of FIG. 7F. The difference between FIG. 7F′ and FIG. 7F is that the top surface of the dielectric wall 114 is equal to or lower than the top surface of the shortened spacer layer 126S.

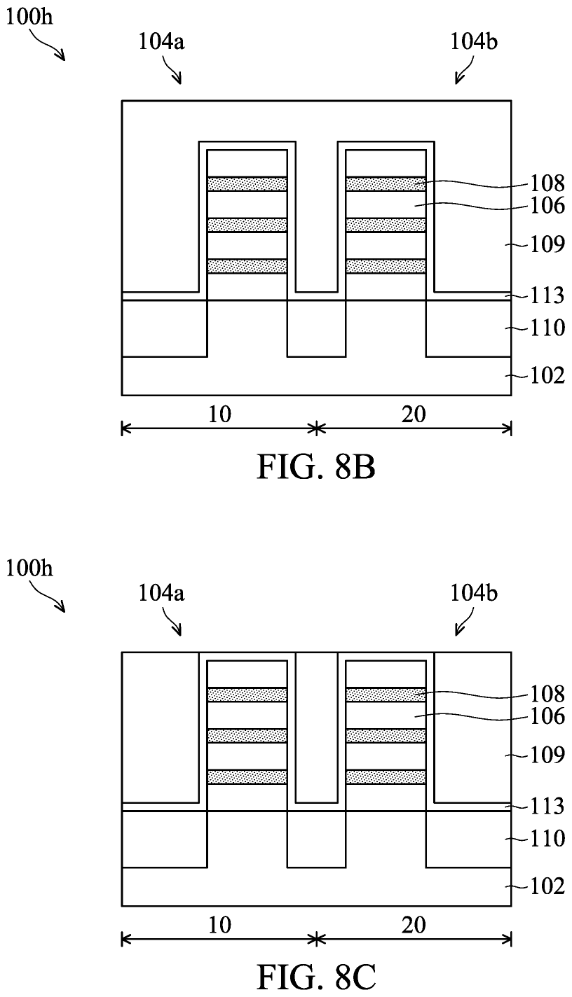

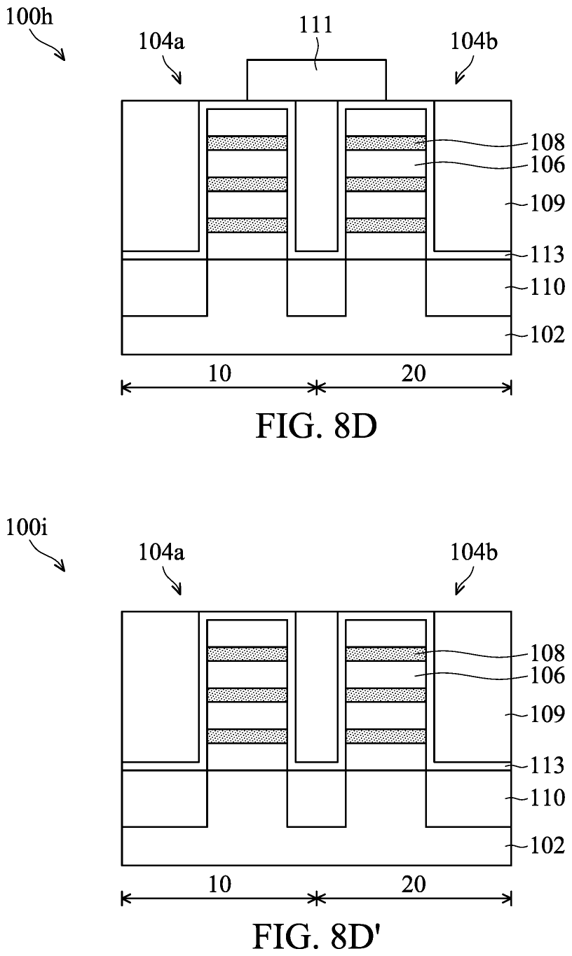

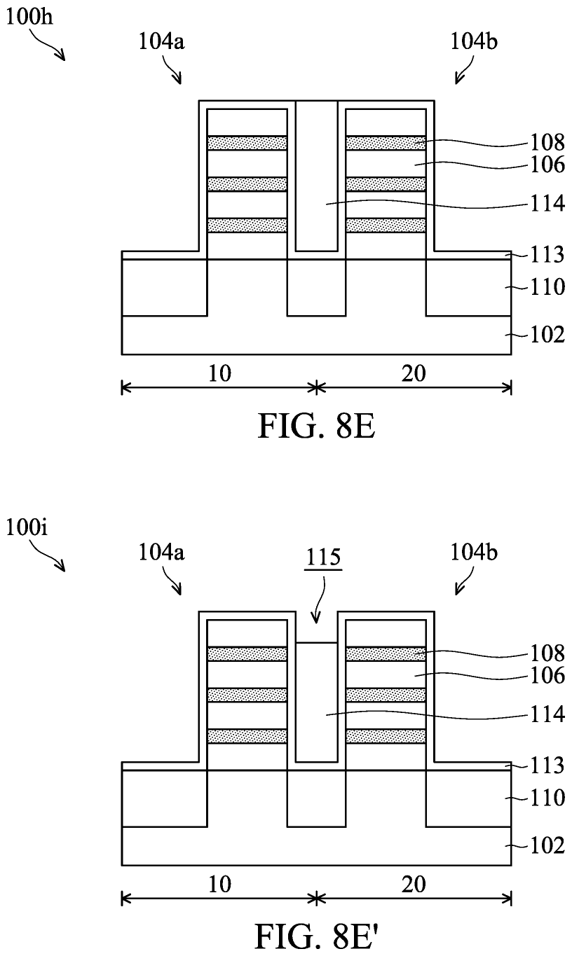

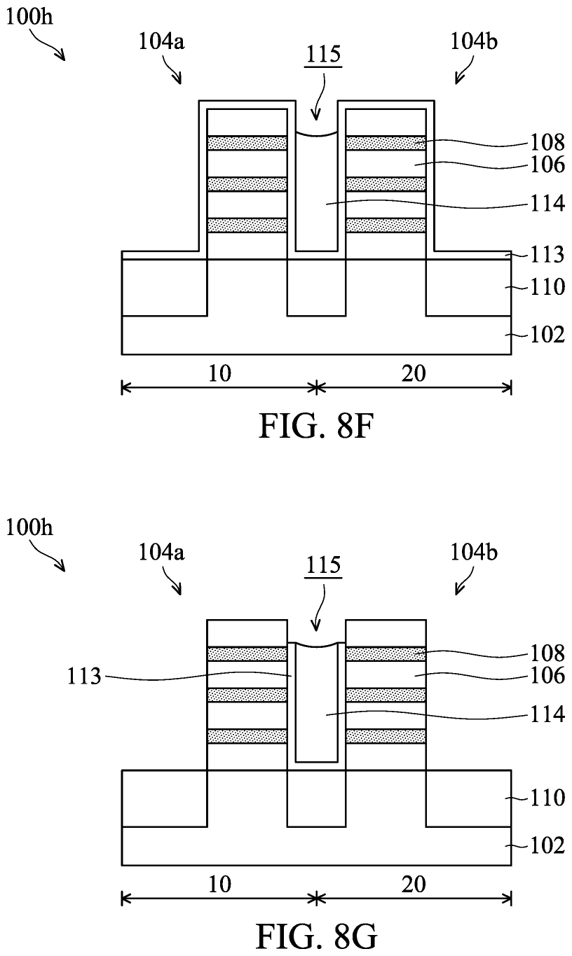

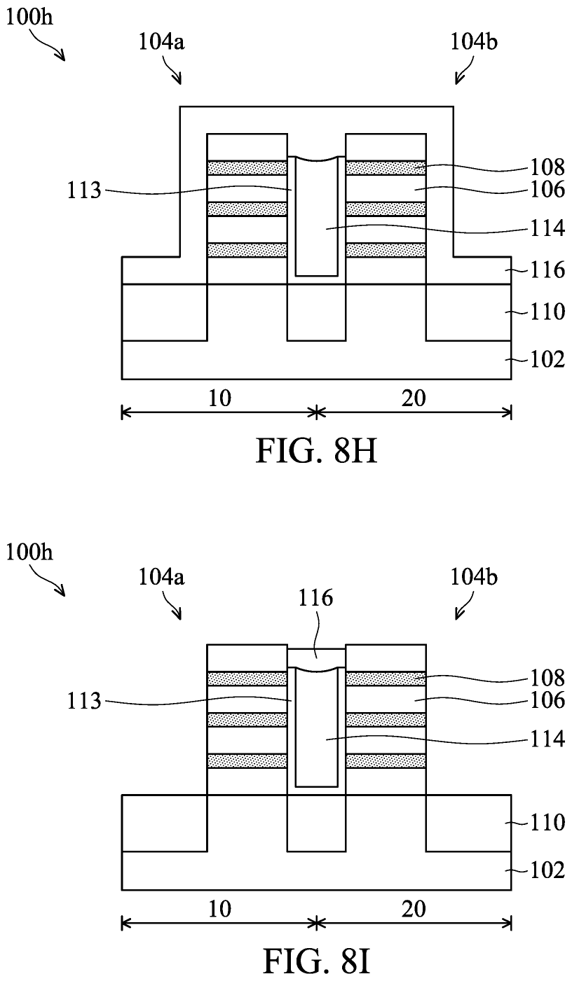

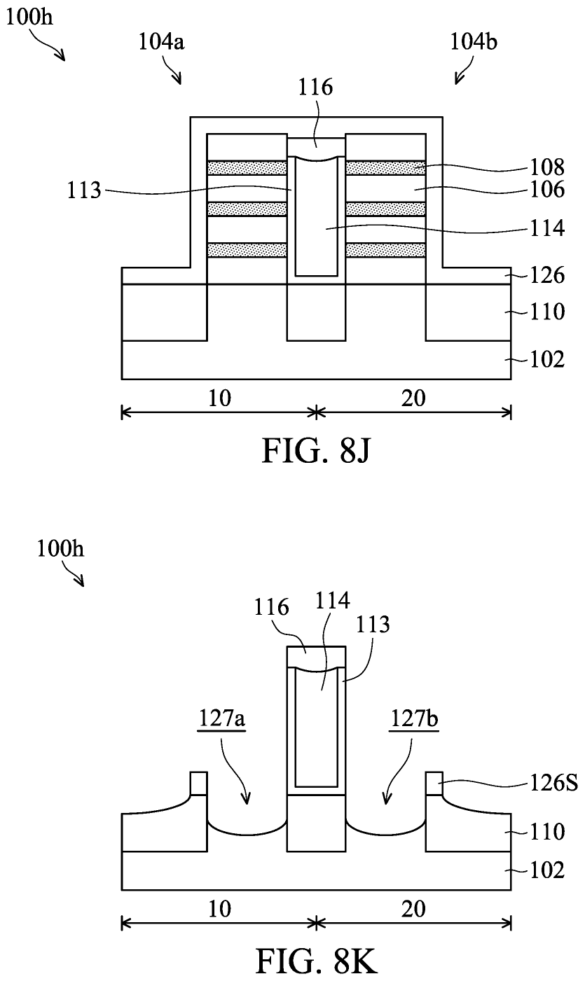

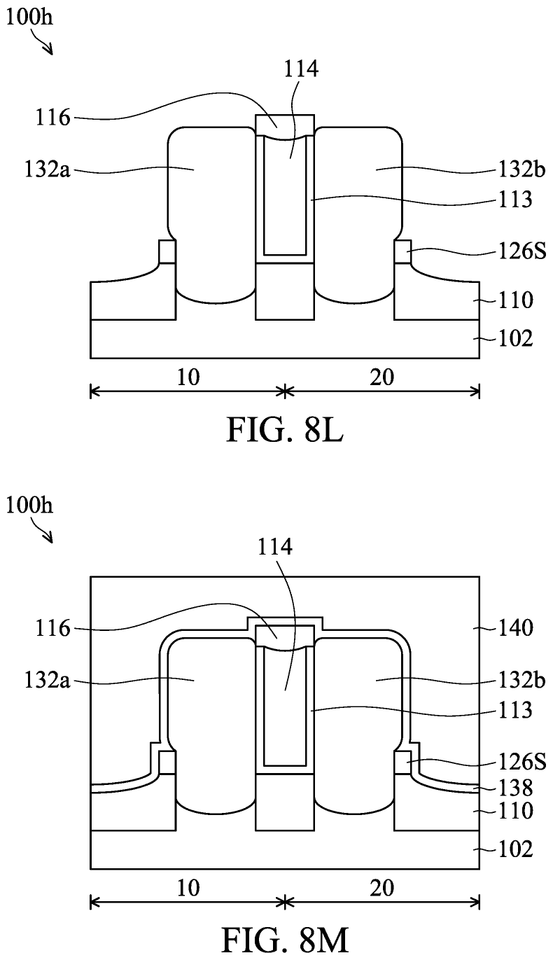

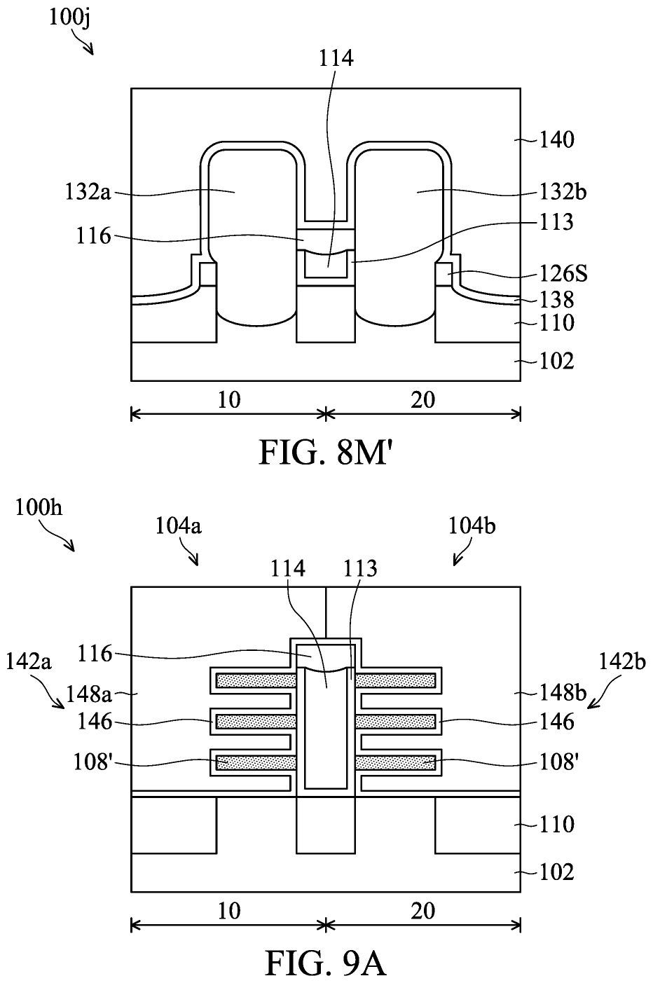

FIGS. 8A to 8M show cross-sectional representations of various stages of manufacturing the semiconductor structure 100h shown along an S/D region, in accordance with some embodiments.

As shown in FIG. 8A, a liner layer 113 is formed over the first stack structure 104a, the second stack structure 104b, and the isolation structure 110, in accordance with some embodiments. In some embodiments, the liner layer 113 is a low k dielectric material with K value in a range from about 3.8 to about 5. In some embodiments, the K value of the liner layer 113 is lower than the K value of the dielectric wall 114. In some other embodiments, the K value of the liner layer 113 is higher than the K value of the dielectric wall 114.

Next, as shown in FIG. 8B, an isolation material 109 is formed over the liner layer 113, in accordance with some embodiments.

Afterward, as shown in FIG. 8C, the top portion of the isolation material 109 is removed to expose the top surface of the liner layer 113, in accordance with some embodiments.

Next, as shown in FIG. 8D, the photoresist layer 111 is formed over the first stack structure 104a, the second stack structure 104b and the isolation material 109, in accordance with some embodiments. Next, the photoresist layer 111 is patterned to form a patterned photoresist layer 111.

Afterward, as shown in FIG. 8E, the portions of the isolation material 109 which are not covered by the photoresist layer 111 are removed, in accordance with some embodiments. The portions of the isolation material 109 are removed by an etching process. As a result, the dielectric wall 114 and the isolation structure 110 are obtained. The dielectric wall 114 is surrounded by the liner layer 113. The top surface of the dielectric wall 114 is substantially leveled with the top surface of the topmost first semiconductor layer 106.

The dielectric wall 114 is between the first stack structure 104a and the second stack structure 104b. The dielectric wall 114 protrudes from the isolation structure 110. The liner layer 113 is in direct contact with the first stack structure 104a and the second stack structure 104b.

Afterward, as shown in FIG. 8F, the top portion of the dielectric wall 114 is removed to form the recess 115, in accordance with some embodiments. The dielectric wall has a recessed top surface. The recessed top surface of the dielectric wall 114 is lower than the topmost surface of the liner layer 113.

FIGS. 8D′ to 8E′ show cross-sectional representations of intermediate stages of manufacturing a semiconductor structure 100i, in accordance with some embodiments. The semiconductor structure 100i of FIG. 8D′ includes elements that are similar to, or the same as, elements of the semiconductor structure 100h of FIG. 8D. The difference between FIG. 8D′ and FIG. 8D is that no photoresist layer is formed over the dielectric wall 114.

As shown in FIG. 8E′, since the space between the first stack structure 104a and the second stack structure 104b is smaller than the space outside of the first stack structure 104a or the second stack structure 104b, the etching rate of the isolation material 109 between the first stack structure 104a and the second stack structure 104b is smaller than the etching rate of the isolation material 109 outside of the first stack structure 104a or the second stack structure 104b. Therefore, the dielectric wall 114 between the first stack structure 104a and the second stack structure 104b is higher than the isolation structure 110. In addition, the top portion of the dielectric wall 114 is removed to form the recess 115, since no photoresist layer is directly formed on the dielectric wall 114. The top surfaces of the first stack structure 104a and the second stack structure 104b are higher than the top surface of the dielectric wall 114.

Afterward, as shown in FIG. 8G, a portion of the liner layer 113 is removed, in accordance with some embodiments. As a result, a top surface and a sidewall surface of the topmost first semiconductor layer 106 are exposed.

Next, as shown in FIG. 8H, the cap layer 116 is formed over the first stack structure 104a, the second stack structure 104b, the isolation structure 110, the liner layer 113 and the dielectric wall 114, in accordance with some embodiments.

In some embodiments, the cap layer 116 is made of high-k dielectric material with a K value greater than 6 (>6). The high-k dielectric material may include hafnium oxide (HfO₂), zirconium oxide (ZrO₂), aluminum oxide (Al₂O₃), hafnium alumina oxide (HfAlOx), hafnium silicon oxide (HfSiOx), hafnium silicon oxynitride, hafnium tantalum oxide (HfTaOx), hafnium titanium oxide (HfTiOx), hafnium zirconium oxide (HfZrOx), or the like. In some embodiments, the cap layer 116 is formed by a LPCVD process, plasma enhanced CVD (PECVD) process, high density plasma CVD (HDP-CVD) process, high aspect ratio process (HARP) process, flowable CVD (FCVD) process, atomic layer deposition (ALD) process, another suitable method, or a combination thereof.

Afterwards, as shown in FIG. 8I, a portion of the cap layer 116 is removed, in accordance with some embodiments. The remaining cap layer 116 is formed on the dielectric wall 114 and between the first stack structure 104a and the second stack structure 104b. The top surface of the cap layer 116 is lower than the top surface of the topmost surface of the first semiconductor layer 106.

Next, as shown in FIG. 8J, the spacer layer 126 is formed along and covering opposite sidewalls of the dummy gate structure 118 and are formed along and covering opposite sidewalls of the source/drain(S/D) regions of the first stack structure 104a and the second stack structure 104b and the dielectric wall 114, in accordance with some embodiments. The spacer layer 126 may be configured to constrain a lateral growth of subsequently formed source/drain (S/D) structure (formed later) and support the first stack structure 104a and the second stack structure 104b.

In some embodiments, the spacer layer 126 is made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the spacer layer 126 is formed by chemical vapor deposition (CVD), atomic vapor deposition (ALD), physical vapor deposition (PVD), another suitable method, or a combination thereof.

Afterwards, as shown in FIG. 8K, a portion of the spacer layer 126 is removed to form the shortened spacer layer 126S, and then a portion of the first stack structure 104a and the second stack structure 104b is removed, in accordance with some embodiments. As a result, the first S/D recess 127a and the second S/D recess 127b are formed, and the top surfaces of the substrate 102 are exposed by the first S/D recess 127a and the second S/D recess 127b.

Next, as shown in FIG. 8L, the first S/D structure 132a is formed in the first recess 127a in the first region 10, and the second S/D structure 132b is formed in the second S/D recess 127b in the second region 20, in accordance with some embodiments. The top surface of the cap layer 116 is higher than the topmost surface of the first S/D structure 132a and the top surface of the second S/D structure 132b.

Next, as shown in FIG. 8M, after the first S/D structure 132a and second S/D structures 132b are formed, the contact etch stop layer (CESL) 138 is conformally formed to cover the first S/D structures 132a, the second S/D structure 132b, and the cap layer 116, and the interlayer dielectric (ILD) layer 140 is formed over the contact etch stop layers 138, in accordance with some embodiments.

FIG. 8M′ shows a cross-sectional view of a semiconductor structure 100j, in accordance with some embodiments. The semiconductor structure 100j of FIG. 8M′ includes elements that are similar to, or the same as, elements of the semiconductor structure 100h of FIG. 8M. The difference between FIG. 8M′ and FIG. 8M is that the top surface of the dielectric wall 114 is equal to or lower than the top surface of the shortened spacer layer 126S, and no cap layer is formed over the dielectric wall 114 and the liner layer 113.

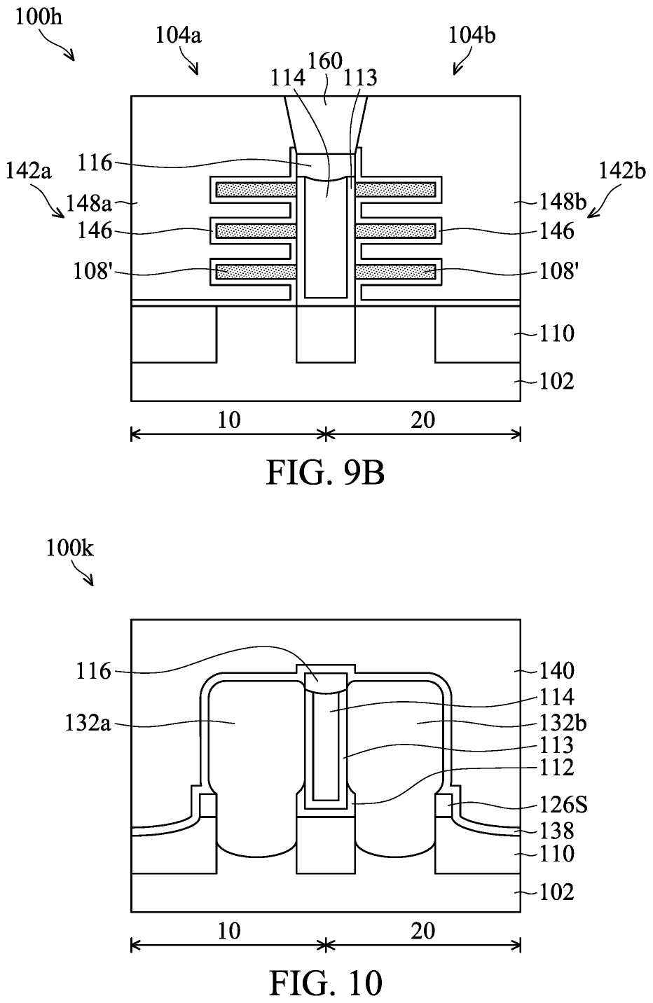

FIGS. 9A-9B show a cross-sectional views of the semiconductor structure 100h, in accordance with some embodiments. The semiconductor structure 100h of FIG. 9A shows a gate region. The semiconductor structure 100h of FIG. 9A includes elements that are similar to, or the same as, elements of the semiconductor structure 100a of FIG. 4A.

As shown in FIG. 9A, the liner layer 113 is connected to the nanostructures 108′, and the dielectric wall 114 is formed over the liner layer 113, and the cap layer 116 is formed over the liner layer 113 and the dielectric wall 114. The first gate structure 142a is formed over the nanostructures 108′ and the second gate structure 142b. The nanostructures 108′ are connected to the first S/D structure 132a in the first region 10, and to the second S/D structures 132b in the second region 20.

Next, as shown in FIG. 9B, the cut structure 160 is formed over the cap layer 116. The cut structure 160 is used to isolate the first gate structure 142a and the second gate structure 142b.

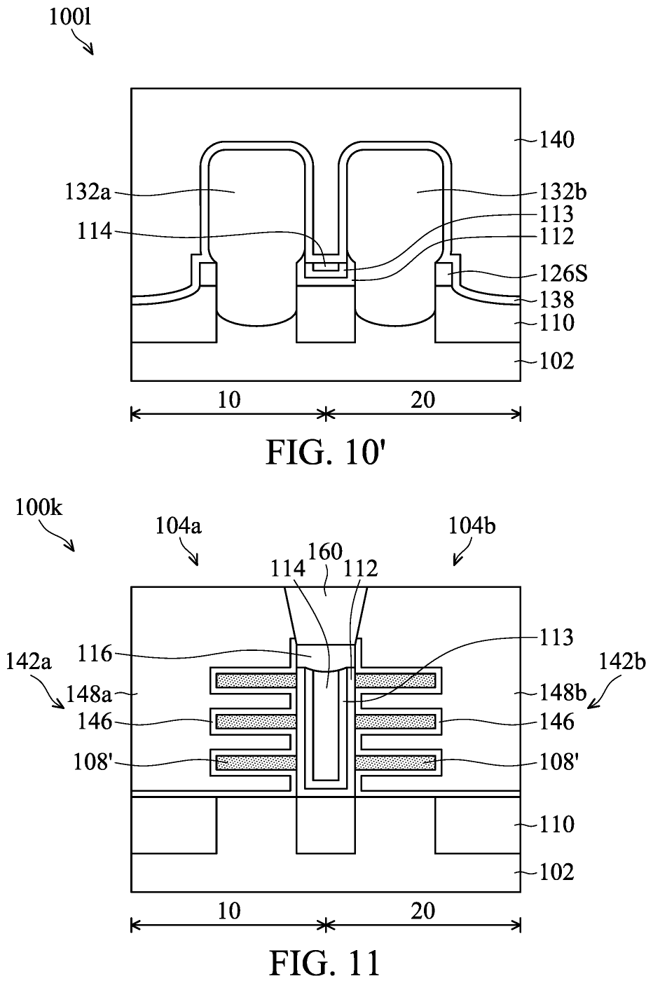

FIG. 10 shows a cross-sectional view of a semiconductor structure 100k, in accordance with some embodiments. The semiconductor structure 100k of FIG. 10 includes elements that are similar to, or the same as, elements of the semiconductor structure 100h of FIG. 8M. The difference between FIG. 10 and FIG. 8M is that a liner layer 112 is formed below the liner layer 113.

As shown in FIG. 10, the liner layer 112 has a U-shaped structure, and the liner layer 113 also has a U-shaped structure. The dielectric wall 114 is surrounded by the liner layer 113 and the liner layer 112. In some embodiments, the K value of the liner layer 112 is higher than the K value of the liner layer 113. In some other embodiments, the K value of the liner layer 112 is lower than the K value of the liner layer 113.

The K value of the cap layer 116 is higher than the K value of the dielectric wall 114, the K value of the liner layer 113 and the K value of the liner layer 112.

In some embodiments, the liner layer 112 is made of oxide, the liner layer 113 is made of nitride, and the dielectric wall 114 is made of oxide. In some embodiments, the liner layer 112 is made of silicon oxide, the liner layer 113 is made of silicon nitride, and the dielectric wall 114 is made of silicon oxide. In some embodiments, the liner layer 112 is used to improve the adhesion between the liner layer 113 and the substrate 102.

FIG. 10′ shows a cross-sectional view of a semiconductor structure 100l, in accordance with some embodiments. The semiconductor structure 100l of FIG. 10′ includes elements that are similar to, or the same as, elements of the semiconductor structure 100k of FIG. 10. The difference between FIG. 910 and FIG. 10 is that the top surface of the dielectric wall 114 is equal to or lower than the top surface of the shortened spacer layer 126S, and no cap layer is formed over the dielectric wall 114 and the liner layer 113.

FIG. 11 shows a cross-sectional view of the semiconductor structure 100k, in accordance with some embodiments. The semiconductor structure 100k of FIG. 11 shows a gate region. The semiconductor structure 100k of FIG. 11 includes elements that are similar to, or the same as, elements of the semiconductor structure 100h of FIG. 9B. The difference between FIG. 11 and FIG. 9B, is that the liner layer 112 surrounds the liner layer 113.

Next, as shown in FIG. 11, the cut structure 160 is formed over the cap layer 116. The cut structure 160 is used to isolate the first gate structure 142a and the second gate structure 142b.

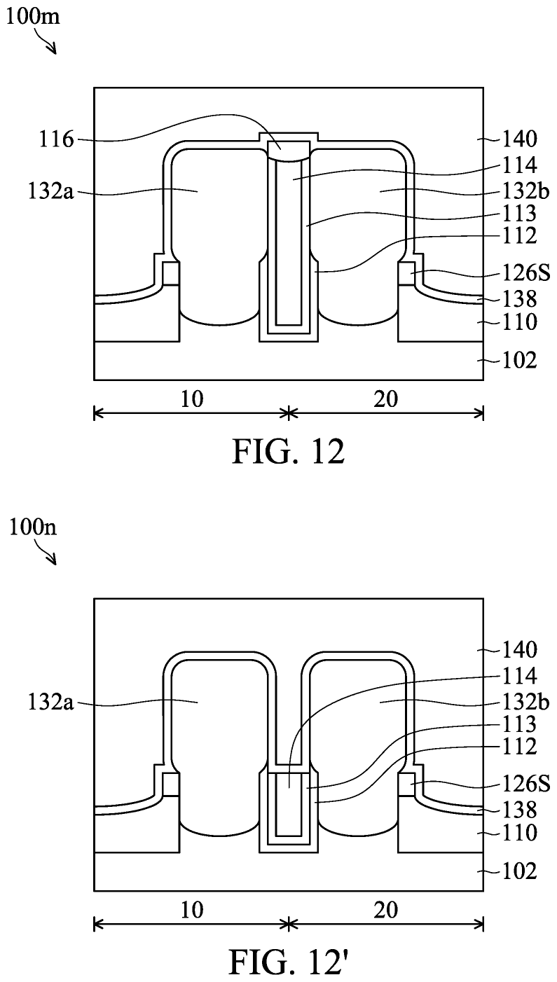

FIG. 12 shows a cross-sectional view of a semiconductor structure 100m, in accordance with some embodiments. The semiconductor structure 100m of FIG. 12 includes elements that are similar to, or the same as, elements of the semiconductor structure 100k of FIG. 10. The difference between FIG. 12 and FIG. 10 is that the liner layer 112 is formed over and in direct contact with the substrate 102. There is no isolation structure between the liner layer 112 and the substrate 102.

FIG. 12′ shows a cross-sectional view of a semiconductor structure 100n, in accordance with some embodiments. The semiconductor structure 100n of FIG. 12′ includes elements that are similar to, or the same as, elements of the semiconductor structure 100m of FIG. 12. The difference between FIG. 12′ and FIG. 12 is that the top surface of the dielectric wall 114 is equal to or lower than the top surface of the shortened spacer layer 126S, and no cap layer is formed over the dielectric wall 114 and the liner layer 113.

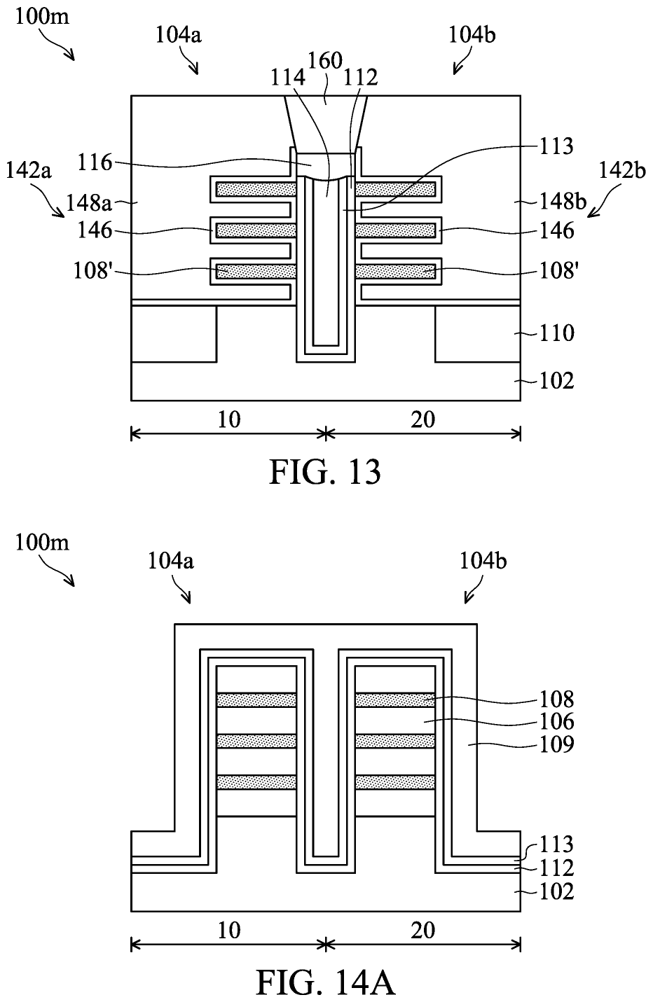

FIG. 13 shows a cross-sectional view of the semiconductor structure 100m, in accordance with some embodiments. The semiconductor structure 100m of FIG. 13 shows a gate region. The semiconductor structure 100m of FIG. 13 includes elements that are similar to, or the same as, elements of the semiconductor structure 100k of FIG. 11.

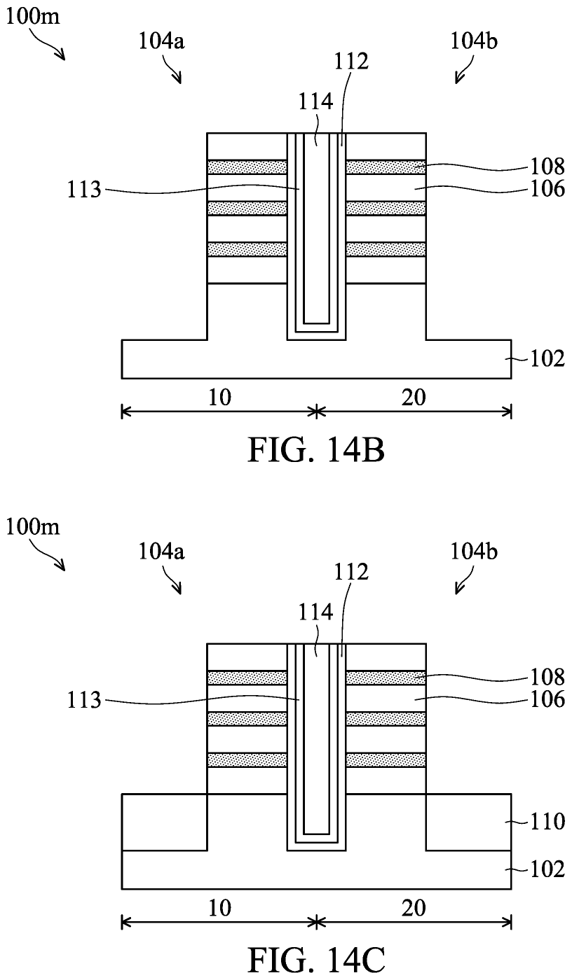

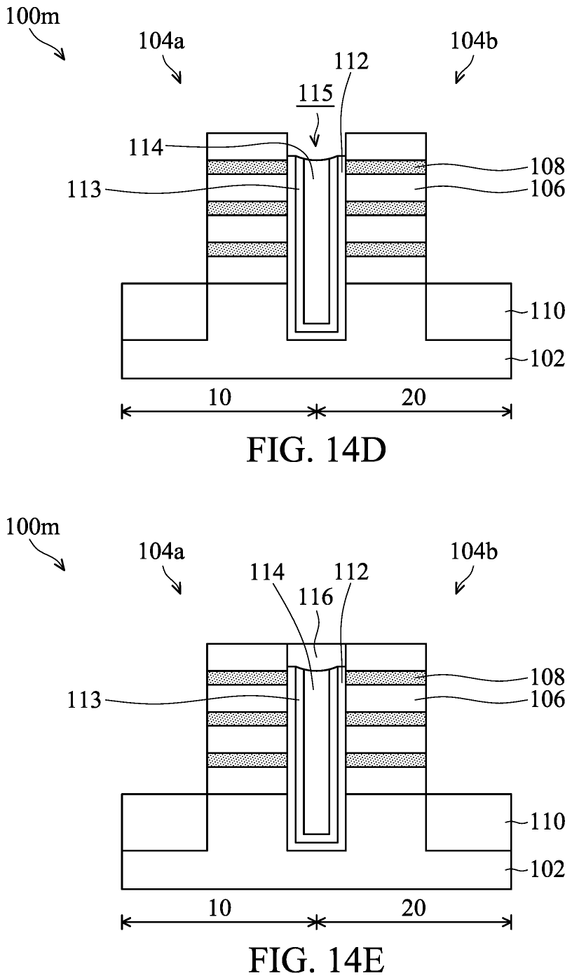

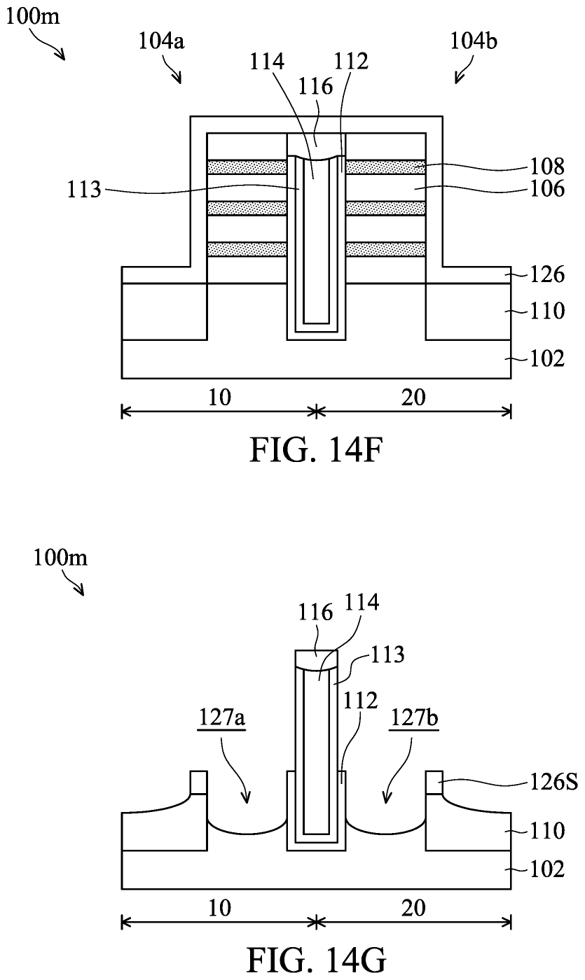

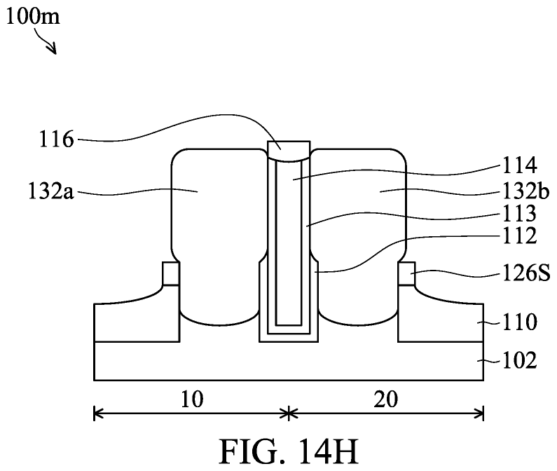

FIGS. 14A to 14H show cross-sectional representations of various stages of manufacturing the semiconductor structure 100m, in accordance with some embodiments. More specifically, FIG. 14A shows the S/D region.

As shown in FIG. 14A, the liner layer 112 is formed over the first stack structure 104a and the second stack structure 104b, the liner layer 113 is formed over the liner layer 112, and the isolation material 109 is formed over the liner layer 113.

Next, as shown in FIG. 14B, a portion of the isolation material 109 is removed to expose the substrate 102 and sidewall of the first stack structure 104a and the second stack structure 104b, in accordance with some embodiments. As a result, the liner layer 112, the liner layer 113 and the dielectric wall 114 are formed between the first stack structure 104a and the second stack structure 104b. More specifically, the liner layer 112 is in direct contact with the first stack structure 104a and the second stack structure 104b.

Next, as shown in FIG. 14C, the isolation structure 110 is formed over the substrate 102, in accordance with some embodiments. It should be noted that the dielectric wall 114 is formed before the isolation structure 110 is formed. There is no isolation structure 110 formed below the dielectric wall 114. The dielectric wall 114 is formed before the isolation structure 110 is formed.

Next, as shown in FIG. 14D, the top portion of the liner layer 112, the top portion of the liner layer 113 and the top portion of the dielectric wall 114 are removed to form the recess 115, in accordance with some embodiments.

Next, as shown in FIG. 14E, the cap layer 116 is formed in the recess, in accordance with some embodiments.

Next, as shown in FIG. 14F, the spacer layer 126 is formed over the cap layer 116, the first stack structure 104a and the second stack structure 104b, and the isolation structure 110, in accordance with some embodiments.

Next, as shown in FIG. 14G, a portion of the spacer layer 126 is removed to form the shortened spacer layer 126S, and then a portion of the first stack structure 104a and the second stack structure 104b is removed to form the first S/D recess 127a and the second S/D recess 127b, in accordance with some embodiments. As a result, the top surfaces of the substrate 102 are exposed by the first S/D recess 127a and the second S/D recess 127b. In addition, a portion of the liner layer 112 is removed, and the top surface of the liner layer 112 is lower than the top surface of the liner layer 113.

Next, as shown in FIG. 14H, the first S/D structure 132a is formed in the first recess 127a in the first region 10, and the second S/D structure 132b is formed in the second S/D recess 127b in the second region 20, in accordance with some embodiments. The top surface of the cap layer 116 is higher than the topmost surface of the first S/D structure 132a and the top surface of the second S/D structure 132b.

The first stack structure 104a includes a number of nanostructures 108′ which extend along the X-axis direction, the second stack structure 104b includes a number of nanostructures 108′ which extend along the X-axis direction. The first gate structure 132a extends along the Y-axis direction. The dielectric wall 114 is connected to the nanostructures 108′ of the first stack structure 104a and the second stack structure 104b, and the dielectric wall 114 is between the first S/D structure 132a and the second S/D structure 132b. In some embodiments, the dielectric wall 114 includes a low-k dielectric material. In some embodiments, the cap layer with high-k dielectric material is formed over the dielectric wall 114. In some embodiments, the dielectric wall 114 is surrounded by the liner layer 113. In some embodiments, the dielectric wall 114 is surrounded by the liner layer 112 and liner layer 113. The dielectric wall 114 with low-k material can reduce the capacitance of the semiconductor structure. Furthermore, the dielectric wall 114 may be void free or seam free since the dielectric wall is formed by a flowable material. Therefore the performance of the semiconductor structure is improved.

It should be appreciated that the semiconductor structures 100a to 100m having the dielectric wall 114 with low-k material described above may also be applied to FinFET structures, although not shown in the figures.

It should be noted that same elements in FIGS. 1A to 14H may be designated by the same numerals and may include similar or the same materials and may be formed by similar or the same processes; therefore such redundant details are omitted in the interest of brevity. In addition, although FIGS. 1A to 14H are described in relation to the method, it will be appreciated that the structures disclosed in FIGS. 1A to 14H are not limited to the method but may stand alone as structures independent of the method. Similarly, although the methods shown in FIGS. 1A to 14H are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes forming a gate structure, a source/drain (S/D) structure adjacent to the gate structure, and an S/D contact structure over the S/D structure. A dielectric wall is formed below the gate structure and the S/D contact structure. The dielectric wall with low-k material can reduce the capacitance of the semiconductor structure. Furthermore, the dielectric wall may be void free or seam free since the dielectric wall is formed by a flowable material. Therefore the performance of the semiconductor structure is improved.

In some embodiments, a semiconductor structure is provided. The semiconductor structure includes a first stack structure formed over a substrate, and the first stack structure includes a plurality of nanostructures that extend along a first direction. The semiconductor structure includes a second stack structure formed adjacent to the first stack structure, and the second stack structure includes a plurality of nanostructures that extend along the first direction. The semiconductor structure includes a first gate structure formed over the first stack structure, and the first gate structure extends along a second direction. The semiconductor structure also includes a dielectric wall between the first stack structure and the second stack structure, and the dielectric wall includes a low-k dielectric material, and the dielectric wall is connected to the first stack structure and the second stack structure.

In some embodiments, a semiconductor structure is provided. The semiconductor structure includes a gate structure formed over a substrate, and a first source/drain (S/D) structure formed adjacent to the gate structure. The semiconductor structure includes a second S/D structure adjacent to the first S/D structure. The semiconductor structure also includes a dielectric wall between the first S/D structure and the second S/D structure. The dielectric wall includes a low-k dielectric material, and a bottom surface of the dielectric wall is lower than a bottom surface of the first S/D structure.

In some embodiments, a method for forming a semiconductor structure is provided. The method includes forming a first stack structure and a second stack structure over a substrate, and forming a dielectric wall between the first stack structure and the second stack structure. The dielectric wall includes a low-k dielectric material. The method further includes removing a portion of the first stack structure to form a recess, and forming an S/D structure in the recess. A portion of the S/D structure is in direct contact with the dielectric wall. The method includes removing a portion of the first stack structure to form a plurality of nanostructures, and the nanostructures are connected to the dielectric wall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first stack structure formed over a substrate, wherein the first stack structure comprises a plurality of nanostructures that extend along a first direction;
a second stack structure formed adjacent to the first stack structure, wherein the second stack structure comprises a plurality of nanostructures that extend along the first direction;
a first gate structure formed over the first stack structure, wherein the first gate structure extends along a second direction; and
a dielectric wall between the first stack structure and the second stack structure, wherein the dielectric wall comprises a low-k dielectric material, and the dielectric wall is connected to the first stack structure and the second stack structure.

2. The semiconductor structure as claimed in claim 1, further comprising:
a first source/drain (S/D) structure formed adjacent to the first gate structure, wherein the first S/D structure is connected to the first stack structure.

3. The semiconductor structure as claimed in claim 2, wherein the dielectric wall has a first portion directly below the first gate structure and a second portion adjacent to the first S/D structure, the first portion has a first width along the second direction, the second portion has a second width along the second direction, and the second width is smaller than the first width.

4. The semiconductor structure as claimed in claim 3, wherein the first portion has a first height along a vertical direction, the second portion has a second height along the vertical direction, and the first height is greater than the second height.

5. The semiconductor structure as claimed in claim 1, wherein a bottom surface of the dielectric wall is lower than a bottom surface of the first S/D structure.

6. The semiconductor structure as claimed in claim 1, further comprising:
a cap layer formed over the dielectric wall, wherein the cap layer comprises a high-k dielectric material.

7. The semiconductor structure as claimed in claim 1, further comprising:
an isolation structure formed over the substrate, wherein the isolation structure and the dielectric wall are made of the same material.

8. The semiconductor structure as claimed in claim 1, further comprising:
a spacer layer adjacent to the first S/D structure, wherein a top surface of the dielectric wall is higher than a top surface of the spacer layer.

9. The semiconductor structure as claimed in claim 1, further comprises:
a liner layer formed on sidewalls of the dielectric wall.

10. A semiconductor structure, comprising:
a gate structure formed over a substrate;
a first source/drain (S/D) structure formed adjacent to the gate structure;
a second S/D structure adjacent to the first S/D structure; and
a dielectric wall between the first S/D structure and the second S/D structure, wherein the dielectric wall comprises a low-k dielectric material, and a bottom surface of the dielectric wall is lower than a bottom surface of the first S/D structure.

11. The semiconductor structure as claimed in claim 10, further comprising:
a cap layer formed over the dielectric wall, wherein the cap layer comprises a high-k dielectric material.

12. The semiconductor structure as claimed in claim 11, wherein an interface between the cap layer and the dielectric wall is lower than a top surface of the first S/D structure.

13. The semiconductor structure as claimed in claim 10, wherein the dielectric wall has a top portion and a bottom portion, and the bottom portion is wider than the top portion.

14. The semiconductor structure as claimed in claim 10, further comprising:
an isolation structure formed over the substrate, wherein the isolation structure and the dielectric wall are made of the same material.

15. The semiconductor structure as claimed in claim 10, wherein a portion of the first S/D structure is in direct contact with the dielectric wall.

16. The semiconductor structure as claimed in claim 10, further comprising:
a spacer layer adjacent to the first S/D structure, wherein a top surface of the dielectric wall is higher than a top surface of the spacer layer.

17. The semiconductor structure as claimed in claim 10, further comprising:
a first stack structure formed over the substrate, wherein the first stack structure comprises a plurality of nanostructures; and
a second stack structure formed adjacent to the first stack structure, wherein the second stack structure comprises a plurality of nanostructures, and the dielectric wall is between the first stack structure and the second stack structure.

18. A method for forming a semiconductor structure, comprising:
forming a first stack structure and a second stack structure over a substrate;
forming a dielectric wall between the first stack structure and the second stack structure, wherein the dielectric wall comprises a low-k dielectric material;
removing a portion of the first stack structure to form a recess;
forming an S/D structure in the recess, wherein a portion of the S/D structure is in direct contact with the dielectric wall; and
removing a portion of the first stack structure to form a plurality of nanostructures, wherein the nanostructures are connected to the dielectric wall.

19. The method for forming the semiconductor structure as claimed in claim 17, further comprising:
removing a portion of the dielectric wall, such that the dielectric wall has a bottom portion and a top portion, and the bottom portion is wider than the top portion.

20. The method for forming the semiconductor structure as claimed in claim 17, further comprising:
simultaneously forming an isolation structure when forming the dielectric wall between the first stack structure and the second stack structure.
